(19) United States
(12) Patent Application Publication
(10) Pub. No.: US 2016/0023904 A1
(43) Pub. Date: Jan. 28, 2016

(54) STRAIN ENGINEERED MICROSTRUCTURES

(71) Applicants: Massachusetts Institute of Technology, Cambridge, MA (US); University of Michigan, The Board of Regents Acting For and On behalf of the C/O Technology Man, Ann Arbor, MI (US)

(72) Inventors: Anastasios John Hart, Cambridge, MA (US); Sei Jin Park, Boston, MA (US); Sameh Hani Tawfick, Champaign, IL (US); Michael FI De Volder, Gent (BE)

(73) Assignees: Massachusetts Institute of Technology, Cambridge, MA (US); University of Michigan, The Board of Regents Acting For and On Behalf of the C/O Technology Man, Ann Arbor, MI (US)

(21) Appl. No.: 14/444,845

(22) Filed: Jul. 28, 2014

(51) Int. Cl. C01B 31/02; C23C 16/52

(52) U.S. Cl. CPC C01B 31/0233; C23C 16/52; C01B 2202/02; C01B 2202/06; C01B 2202/36; C01B 2202/20; C01B 2202/08

(57) ABSTRACT

The present invention generally relates to articles comprising microstructures and methods for forming microstructures. The microstructures may be mechanically coupled to impart complex three dimensional shapes. For example, one or more microstructures may be grown on a substrate at different average growth rates, resulting in curved microstructures.

### FIELD OF THE INVENTION

The present invention generally relates to articles comprising microstructures and methods for forming microstructures.

### BACKGROUND

Scalable fabrication of microstructures that mimic the hierarchical surface designs found in nature has been a long-standing aspiration of material scientists. While symbiotic growth of the integrated circuit (IC) and micro electro mechanical systems (MEMS) industries has enabled innovations in 3D fabrication that leverage semiconductor processing tools, these methods, such as interference or inclined exposure lithography are typically limited to arrays of identical structures. Rapid prototyping methods such as direct laser writing, multiphoton lithography, and focused ion beam milling can create arbitrary forms but are serial, and therefore have lower areal throughput. It is also especially difficult to fabricate surface structures having curved and/or re-entrant geometries.

Accordingly, improved materials and methods are needed.

### SUMMARY OF THE INVENTION

The present invention provides articles comprising structures and methods for forming microstructures.

In one embodiment, an article is provided. The article comprises a substrate, a first microstructure adjacent the substrate, a second microstructure adjacent the first microstructure, wherein the first microstructure has a greater average density, greater average cross-sectional dimension, greater average growth rate, and/or different chemical composition than the second microstructure and wherein the first structure has a appreciably non-zero tip angle relative to the vertical when measured at the distal end of the first microstructure.

Methods for growing structures are also provided. In one embodiments, a method for growing structures comprises providing a first substrate portion including a first reaction site, providing a second substrate portion adjacent the first substrate portion including a second reaction site, introducing a reaction species to the first reaction site and the second reaction site, growing a first microstructure and/or population of nanostructures on the first reaction site at a first average growth rate, growing a second microstructure and/or population of nanostructures on the second reaction site at a second average growth rate, wherein the second average growth rate is less than the first average growth rate.

In another embodiments, a method for growing structures comprises growing at least two microstructures and/or populations of nanostructures, the at least two structures and/or populations have lateral cross-sectional dimensions of at least about 50 nm, simultaneously on a substrate at different growth rates, via exposure to growth conditions applied uniformly to portions of the substrate at which the at least two structures are grown.

Other advantages and novel features of the present invention will become apparent from the following detailed description of various non-limiting embodiments of the invention when considered in conjunction with the accompanying figures. In cases where the present specification and a document Incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

FIGS. 1A-1D include schematic diagrams illustrating exemplary microstructures, according to one set of embodiments;

FIG. 2 includes a schematic diagram, according to one set of embodiments, of an exemplary microstructure;

FIGS. 3A-B show the fabrication of exemplary microstructures; according to one set of embodiments;

FIGS. 4A-B show exemplary microstructures; according to another set of embodiments;

FIGS. 5A-5D show the fabrication of exemplary microstructures, according to one set of embodiments;

FIGS. 6A-6E shows a microstructure comprising nanotubes; according to another set of embodiments;

FIGS. 7A-7D shows the fabrication of exemplary microstructures, according to one set of embodiments;

FIGS. 8A-8D shows the fabrication of exemplary microstructures, according to another set of embodiments.

FIGS. 9A-9F shows the fabrication of exemplary microstructures, according to another set of embodiments.

Other aspects, embodiments and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### DETAILED DESCRIPTION

The present invention generally relates to articles comprising structures and methods for forming these structures, in which structures having different properties, and/or non-linear structures, can be fabricated in proximity to each other and optionally under similar and/or identical growth conditions applied to a substrate or substrates at which the structures are fabricated. Microstructures, themselves optionally made up of nanostructures and/or other components (which can be populations of nanostructures such as nanotubes), are described primarily herein in this context, yet it is to be understood that wherever “microstructures” are discussed in this context, structures of other dimensions can be fabricated in line with the principles of the invention. In some cases, the methods may comprise the fabrication of one or more microstructures on one or more substrates such that the interaction between one or more microstructures and one or more substrates results in the formation of curved microstructures. The methods may comprise, in some embodiments, the fabrication of two or more microstructures such that the interaction between the two or more microstructures results in the formation of curved microstructures. In one set of embodiments, the growth rate of the one or more microstructures differs. In some instances, the difference in growth rates of the one or more microstructures may result in curved microstructures.

Articles comprising microstructures are also provided. In some instances, the articles may comprise relatively closely-spaced microstructures. In certain embodiments, the articles may comprise one or more microstructures in direct contact. In one set of embodiments, the one or more microstructures comprise nanotubes (e.g., carbon nanotubes).

Articles comprising microstructures, as described herein, may have desirable optical properties such as the ability to absorb a high fraction of incident electromagnetic radiation. In some cases, the microstructures may enhance the mechanical properties of an article, for example, providing mechanical reinforcement at an interface between two articles. The microstructures may also enhance thermal and/or electronic properties of an article. In some cases, the microstructures may provide the ability to tailor one or more anisotropic properties of a material, including mechanical, thermal, electrical, and/or other properties. In some cases, the microstructures may alter the wettability or adhesion of an article.

As used herein, the term “microstructure” refers to chemical structures having a cross-sectional dimension (e.g., a length, a diameter, or the like) on the order of micrometers. It should be understood, that while much of the description herein focuses on microstructures, this is by no means limiting, and structures with larger (e.g., millimeter-scale) and structures with smaller (e.g., nanometer-scale) dimensions (e.g., a length, a diameter, or the like) may be employed where appropriate. For example, in some cases, the microstructure and/or population of nanostructures such as nanotubes has a cross-sectional dimension on the order of microns to millimeters or more, resulting in an aspect ratio greater than 10, 100, 1000, 10,000, or greater. In some cases, structures of the invention, such as microstructures and/or populations of nanostructures, or nanostructures themselves may have an average maximum cross-sectional dimension of less than about 10 mm, less than about 5 mm, less than about 1 mm, less than about 100 μm, less than about 50 μm, less than about 10 μm, less than about 5 μm, less than about 1 μm, less than about 250 nm, less than about 100 nm, less than about 75 nm or, in some cases, less than about 50 nm. As used herein, the “maximum cross-sectional dimension” refers to the largest distance between two opposed boundaries of an individual structure that may be measured. In some instances, the microstructure has a cylindrical or pseudo-cylindrical shape. The microstructure may comprise, for example, a plurality of nanostructures (e.g., nanotubes, nanowires, or nanofibers). In another set of embodiments, the microstructure and/or population of nanostructures such as nanotubes has a maximum cross-sectional dimension of at least about 50 nm, or at least about 75 nm, or at least about 100 nm, or at least about 250 nm, or at least about 1 μm, or at least about 5 μm, or at least about 10 μm, or at least about 50 μm, or at least about 100 μm, or at least about 1 mm, or at least about 5 mm or at least about 10 mm. In some cases, the invention is notable for relatively large (greater than a particular level of maximum cross-sectional dimension) structures that differ from each other.

In one set of embodiments, lateral cross-sectional dimension is an important dimension. “lateral cross-sectional dimension,” as used herein, in the context of a structure adjacent a substrate, is the largest dimension of the structure (e.g., microstructure and/or population of nanostructures such as nanotubes) parallel to the substrate (i.e., a lateral dimension of the structure relative to the substrate)

As used herein, the term “nanostructure” refers to elongated chemical structures having a diameter on the order of nanometers and a length on the order of microns to millimeters, resulting in an aspect ratio greater than 10, 100, 1000, 10,000, or greater. In some cases, the nanostructure may have a diameter less than 1 μm, less than 100 nm, 50 nm, less than 25 nm, less than 10 nm, or, in some cases, less than 1 nm. Typically, the nanostructure may have a cylindrical or pseudo-cylindrical shape. In some cases, the nanostructure may be a nanotube, such as a carbon nanotube.

In some embodiments, the microstructures used in the systems and methods described herein may be grown on a substrate (e.g., a growth substrate). In other embodiments, the microstructures may be provided separately from their growth substrate, either attached to another substrate, or as a self-supporting structure detached from any substrate.

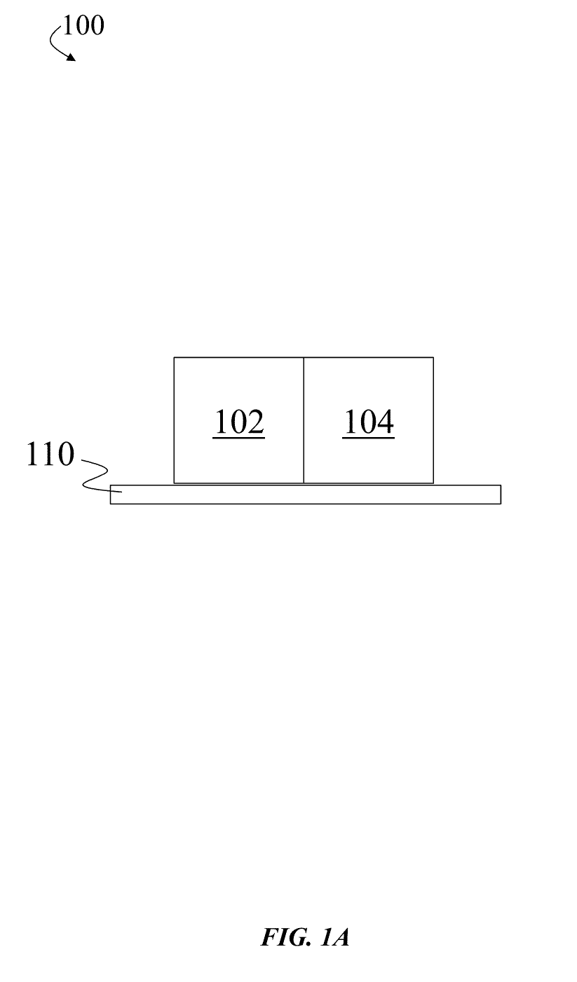

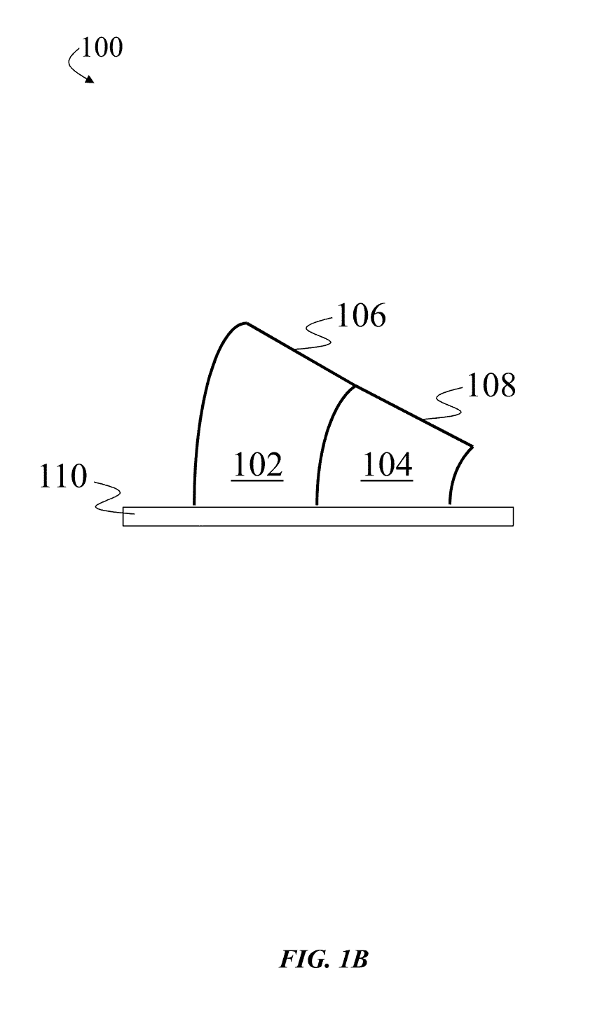

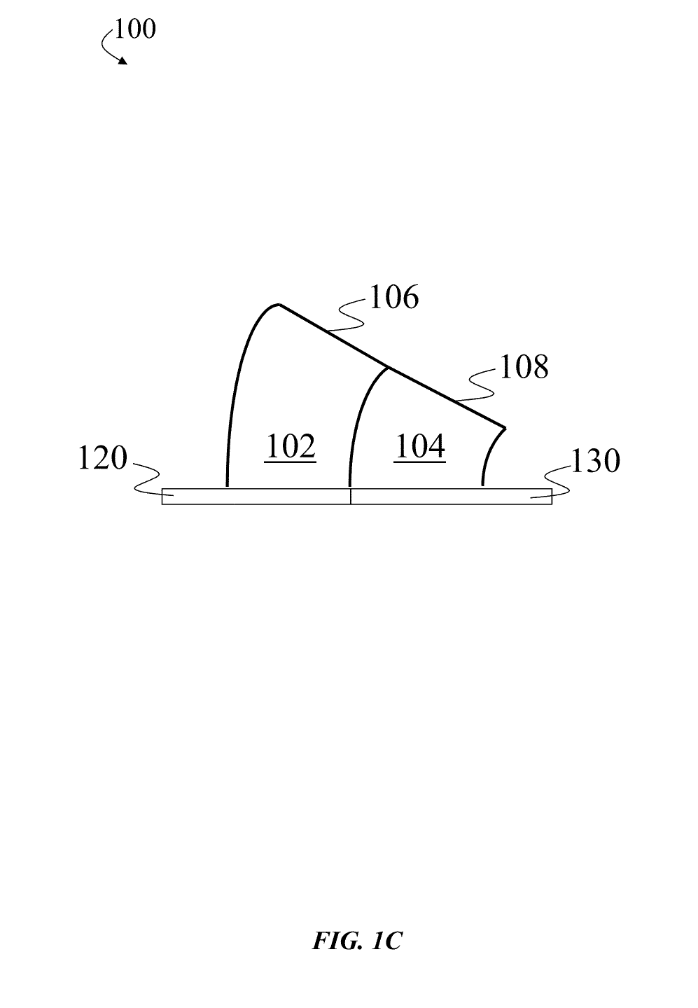

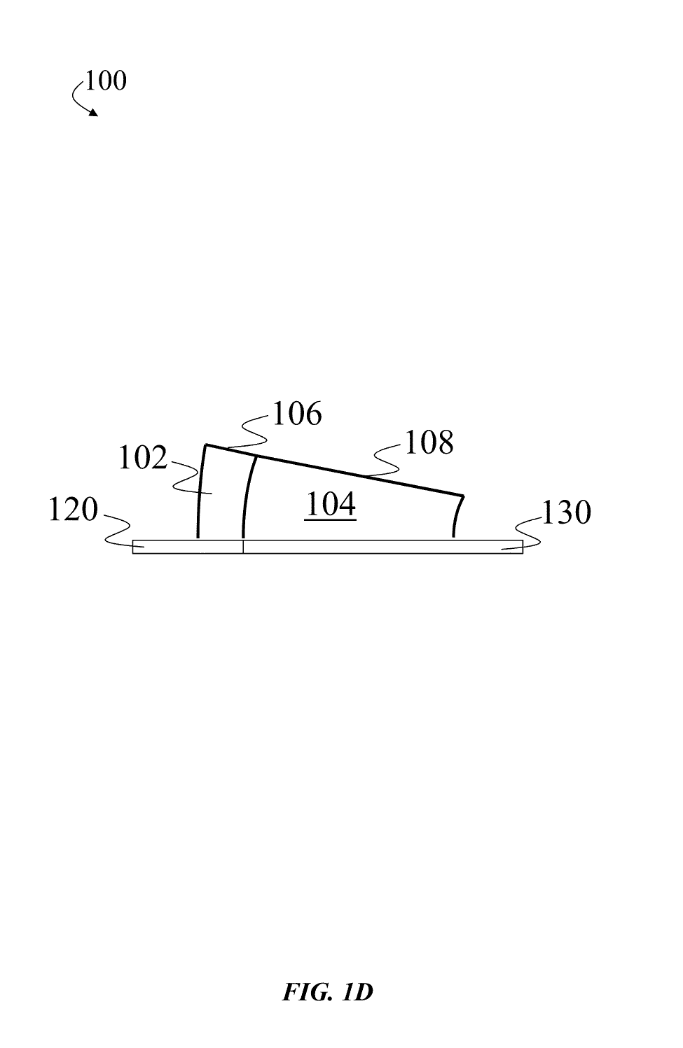

In some embodiments, articles comprising microstructures are provided. For example, FIG. 1 includes a schematic illustration of an article comprising one or more microstructures (e.g., a first microstructure and a second microstructure) in contact with a substrate. In some embodiments, as illustrated in FIG. 1A, article 100 comprises first microstructure 102 and second microstructure 104. First microstructure 102 and second microstructure 104 are both in contact with substrate 110. In certain embodiments, first structure 102 is in direct contact with second structure 104.

In some cases, two or more microstructures may be interconnected, for instance, via bonds or mechanical entanglement. For example, the microstructures may be interconnected via covalent bonds (e.g. carbon-carbon, carbon-oxygen, etc.), ionic bonds, hydrogen bonds, dative bonds, or the like. Two or more microstructures may also be interconnected via Van der Waals interactions in some cases. In certain embodiments, the two or more microstructures may comprise a plurality of nanostructures (e.g., nanotubes) wherein the nanostructures of the two or more microstructures are entangled. For example, the nanostructures of a first microstructure may be, in some cases, entangled with the nanostructures of a second microstructure. In some cases, one or more microstructures may form a self-supporting structure. As used herein, a “self-supporting structure” refers to a structure (e.g., solid, non-solid) having sufficient stability or rigidity to maintain its structural integrity (e.g., shape) without external support along surfaces of the structure.

In some embodiments, two or more microstructures are mechanically coupled. That is to say, entanglements, covalent bonds, ionic bonds, hydrogen bonds, dative bones, and/or Van der Waals interactions, enable the transmission of mechanical load between the two or more microstructures. For example, in some cases, the growth of a first microstructure affects the morphology, growth, and/or strain profile of a second microstructure mechanically coupled to the first microstructure. In some embodiments, the shape of the one or more microstructures is altered by such mechanical coupling.

The one or more microstructures may comprise any suitable material, as described in more detail below. Non-limiting examples of suitable microstructure materials include metals, ceramics, polymers, biomolecules, nanomaterials (e.g., nanotubes, nanowires, nanofibers, or the like), or combinations thereof. In certain embodiments, the one or more microstructures comprise the same material. In some cases, the one or more microstructures may comprise different materials (e.g., different chemical compositions). For example, the first structure may comprise a first material and the second structure may comprise a second material (e.g., a first chemical composition and a second chemical composition). Those skilled in the art will understand that different materials (e.g., different chemical compositions) refers to more than what may occur through defect type differences (e.g., due to manufacturing processes). That is to say, in some cases, the materials are compositionally distinguishable (e.g., distinguishable in phase, material type (e.g., metals and polymers), atomic structure (e.g., heteroatom, chemical formula), secondary structure (e.g., single-walled vs. multi-walled), etc.).

In some cases, the microstructures may be grown on a substrate. The microstructures may be grown on the substrate using either a batch process or a continuous process. In one set of examples, the microstructures may be synthesized by contacting a microstructure precursor material (e.g., a reactive species) with a catalyst material, for example, positioned on the surface of the substrate. In some embodiments, the microstructure precursor material may be a nanotube precursor material and may comprise one or more fluids, such as a hydrocarbon gas, hydrogen, argon, nitrogen, combinations thereof, and the like. Those of ordinary skill in the art would be able to select the appropriate combination of nanotube precursor material, catalyst material, and set of conditions for the growth of a particular nanostructure. For example, carbon nanotubes may be synthesized by reaction of a C₂H₄/H₂ mixture with a catalyst material, such as nanoparticles of Fe arranged on an Al₂O₃ support. Examples of suitable microstructure fabrication techniques are discussed in more detail in International Patent Application Serial No. PCT/US2007/011914, filed May 18, 2007, entitled “Continuous Process for the Production of Nanostructures Including Nanotubes,” published as WO 2007/136755 on Nov. 29, 2007, which is incorporated herein by reference in its entirety. Additional examples of suitable microstructure fabrication techniques are discussed in more detail in U.S. patent application Ser. No. 12/629,301, filed Dec. 2, 2009, entitled “Transformation of Nanostructure Arrays,” published as US 2010/0294424 on Nov. 25, 2010, which is incorporated herein by reference in its entirety. Additional details regarding substrates, precursor materials, and catalysts are provided below.

In some embodiments in which the microstructures are grown on a substrate, the one or more microstructures may comprise a plurality of substantially aligned nanostructures (e.g., nanotubes) oriented such that the long axes of the nanostructures are substantially non-planar with respect to the surface of the substrate. The term “long axis” is used to refer to the imaginary line drawn parallel to the longest length of the nanostructure and intersecting the geometric center of the nanostructure. In some cases, the long axes of the nanostructures are oriented in a substantially perpendicular direction with respect to the surface of the growth substrate, forming a nanostructure “forest.” An advantageous feature of some embodiments of the invention may be that the alignment of nanostructures in the nanostructure “forest” may be substantially maintained, even upon subsequent processing (e.g., application of a force to the forest, transfer of the forest to other surfaces, and/or combining the forests with secondary materials such as polymers, metals, ceramics, piezoelectric materials, piezomagnetic materials, carbon, and/or fluids, among other materials).

As used herein, the term “nanotube” is given its ordinary meaning in the art and refers to a substantially cylindrical molecule or nanostructure comprising a fused network of primarily six-membered aromatic rings. In some cases, nanotubes may resemble a sheet of graphite formed into a seamless cylindrical structure. It should be understood that the nanotube may also comprise rings or lattice structures other than six-membered rings. Typically, at least one end of the nanotube may be capped, i.e., with a curved or nonplanar aromatic group. Nanotubes may have a diameter of the order of nanometers and a length on the order of millimeters, or, on the order of tenths of microns, resulting in an aspect ratio greater than 100, 1000, 10,000, or greater. In some cases, the nanotube is a carbon nanotube (CNT). The term “carbon nanotube” refers to nanotubes comprising primarily carbon atoms and includes single-walled nanotubes (SWNTs), double-walled nanotubes (DWNTs), multi-walled nanotubes (MWNTs) (e.g., concentric carbon nanotubes), inorganic derivatives thereof, and the like. In some embodiments, the carbon nanotube is a single-walled carbon nanotube. In some cases, the carbon nanotube is a multi-walled carbon nanotube (e.g., a double-walled carbon nanotube). In some cases, the nanotube may have a diameter less than 1 μm, less than 100 nm, 50 nm, less than 25 nm, less than 10 nm, or, in some cases, less than 1 nm. In one set of embodiments the nanotubes have an average diameter of 50 nm or less, and are arranged in composite articles as described herein. Additional nanostructure materials include semiconductor nanowires such as silicon (Si) nanowires, indium-gallium-arsenide (InGaAs) nanowires, and nanotubes comprising boron nitride (BN), silicon nitride (Si₃N₄), silicon carbide (SiC), dichalcogenides such as (WS₂), oxides such as titanium dioxide (TiO₂) and molybdenum trioxide (MoO₃), and boron-carbon-nitrogen compositions such as BC₂N₂ and BC₄N.

In cases where the one or more microstructures comprise the same material (e.g., the same chemical composition), the one or more microstructures may differ in material properties (e.g., average growth rate, average density, average cross-sectional dimension, mechanical properties, etc.). In some embodiments, the differences in material properties (e.g., average growth rate, average density, average cross-sectional dimension, mechanical properties, etc.) may occur under uniform growth conditions. In certain embodiments, the differences in material properties as described herein may result from differences in a substrate on which the one or more microstructures are fabricated and/or grown.

In some cases, the one or more microstructures may have a different average growth rate. For example, in some embodiments, an article and/or method described herein comprises a first microstructure having a first average growth rate and a second microstructure having a second average growth rate. One or more microstructures may have an average growth rate ranging between about 0.1 μm/minute to about 1000 μm/minute. For example, the average growth rate of one or more microstructures may be greater than or equal to about 0.1 μm/minute, greater than or equal to about 0.5 μm/minute, greater than or equal to about 1 μm/minute, greater than or equal to about 2 μm/minute, greater than or equal to about 5 μm/minute, greater than or equal to about 10 μm/minute, greater than or equal to about 20 μm/minute, greater than or equal to about 30 μm/minute, greater than or equal to about 50 μm/minute, greater than or equal to about 75 μm/minute, greater than or equal to about 100 μm/minute, greater than or equal to about 250 μm/minute, greater than or equal to about 500 μm/minute, or greater than or equal to about 750 μm/minute. In certain embodiments, the average growth rate of one or more microstructures may be less than or equal to about 1000 μm/minute, less than or equal to about 750 μm/minute, less than or equal to about 500 μm/minute, less than or equal to about 250 μm/minute, less than or equal to about 100 μm/minute, less than or equal to about 75 μm/minute, less than or equal to about 50 μm/minute, less than or equal to about 30 μm/minute, less than or equal to about 20 μm/minute, less than or equal to about 10 μm/minute, less than or equal to about 5 μm/minute, less than or equal to about 2 μm/minute, less than or equal to about 1 μm/minute, or less than or equal to about 0.5 μm/minute. Combinations of the above-referenced ranges are also possible.

In certain embodiments, the first average growth rate (e.g., the average growth rate of the first microstructure) is greater than the second average growth rate (e.g., the average growth rate of the second microstructure). In some embodiments, the first average growth rate is between about 0.1% and about 1000% greater than the second average growth rate. In certain embodiments, the first average growth rate is at least about 0.1%, at least about 0.5%, at least about 1%, at least about 2%, at least about 5%, at least about 10%, at least about 15%, at least about 20%, at least about 30%, at least about 50%, at least about 70%, at least about 90%, at least about 100%, at least about 200%, at least about 400%, at least about 500%, at least about 800%, at least about 1000%, or at least about 5000% greater than the second average growth rate. In some embodiments, the first average growth rate is less than or equal to about 5000%, less than or equal to about 1000%, less than or equal to about 800%, less than or equal to about 500%, less than or equal to about 400%, less than or equal to about 200%, less than or equal to about 100%, less than or equal to about 90%, less than or equal to about 80%, less than or equal to about 70%, less than or equal to about 50%, less than or equal to about 30%, less than or equal to about 20%, less than or equal to about 15%, less than or equal to about 10%, less than or equal to about 5%, less than or equal to about 2%, less than or equal to about 1%, or less than or equal to about 0.5% greater than the second average growth rate. Combinations of the above-referenced ranges are also possible (e.g., the first average growth rate is between about 1% and about 5%, between about 10% and about 100%, between about 100% and about 1000%, or between about 1000% and about 5000% greater than the second average growth rate). As described in more detail below, the average growth rate of the microstructure on a substrate may be controlled by the selection of one or more of a substrate material, a substrate thickness, a catalyst material, or a reactive species.

In some embodiments, the one or more microstructures may have different average densities. For example, in certain embodiments, a first microstructure has a first average density (e.g., the average density of the first microstructure) and a second microstructure has a second average density (e.g., the average density of the second microstructure). In some cases, the first average density and the second average density may be the same or different. In some embodiments, the average density of the one or more microstructures may be between about 0.01 g/cc and about 10 g/cc. For example, in some embodiments, the average density of one or more microstructures is greater than or equal to about 0.01 g/cc, greater than or equal to about 0.02 g/cc, greater than or equal to about 0.05 g/cc, greater than or equal to about 0.10 g/cc, greater than or equal to about 0.25 g/cc, greater than or equal to about 0.5 g/cc, greater than or equal to about 1.0 g/cc, greater than or equal to about 2.0 g/cc, greater than or equal to about 3.0 g/cc, greater than or equal to about 5.0 g/cc, greater than or equal to about 7.0 g/cc, or greater than or equal to about 9.0 g/cc. In certain embodiments, the average density of one or more microstructures is less than about 10 g/cc, less than about 9.0 g/cc, less than about 7.0 g/cc, less than about 5.0 g/cc, less than about 3.0 g/cc, less than about 2.0 g/cc, less than about 1.0 g/cc, less than about 0.5 g/cc, less than about 0.3 g/cc, less than about 0.1 g/cc, less than about 0.05 g/cc, or less than about 0.02 g/cc. Combinations of the above-referenced ranges are also possible (e.g., between about 0.01 g/cc and about 0.1 g/cc, between about 0.1 g/cc and about 1.0 g/cc, between about 1.0 g/cc and about 10 g/cc).

In some embodiments, the first average density is between about 0.1% and about 1000% greater than the second average density. In certain embodiments, the first average density is at least about 0.1%, at least about 0.5%, at least about 1%, at least about 2%, at least about 5%, at least about 10%, at least about 15%, at least about 20%, at least about 30%, at least about 50%, at least about 70%, at least about 90%, at least about 100%, at least about 200%, or at least about 400% greater than the second average density. In some embodiments, the first average density is less than or equal to about 500%, less than or equal to about 400%, less than or equal to about 200%, less than or equal to about 100%, less than or equal to about 90%, less than or equal to about 80%, less than or equal to about 70%, less than or equal to about 50%, less than or equal to about 30%, less than or equal to about 20%, less than or equal to about 15%, less than or equal to about 10%, less than or equal to about 5%, less than or equal to about 2%, less than or equal to about 1%, or less than or equal to about 0.5% greater than the second average density. Combinations of the above-referenced ranges are also possible (e.g., the first average density is between about 1% and about 5%, between about 10% and about 100% greater than the second average)). As described in more detail below, the average density of the microstructure on a substrate may be controlled by the selection of one or more of a substrate material, a substrate thickness, a catalyst material, or a reactive species. In some embodiments, the average density of a microstructure is determined by scanning electron microscopy, small angle x-ray scattering, or the like. Those skilled in the art would be able to select and appropriate method for measuring the average density of a microstructure.

In some embodiments, the one or more microstructures have different average cross-sectional dimensions. In some such embodiments, the average cross-sectional dimension may refer to the diameter of the microstructure (e.g., the diameter of the microstructure where the microstructure contacts the substrate). In certain embodiments, a first microstructure has a first average cross-sectional dimension (e.g., the average cross-sectional dimension of the first microstructure) and a second microstructure has a second average cross-sectional dimension (e.g., the average cross-sectional dimension of the second microstructure). In some embodiments, the first average cross-sectional dimension is between about 0.1% and about 1000% greater than the second average cross-sectional dimension. In certain embodiments, the first average cross-sectional dimension is at least about 0.1%, at least about 0.5%, at least about 1%, at least about 2%, at least about 5%, at least about 10%, at least about 15%, at least about 20%, at least about 30%, at least about 50%, at least about 70%, at least about 90%, at least about 100%, at least about 200%, at least about 400%, at least about 500%, at least about 800%, at least about 1000%, or at least about 5000% greater than the second average cross-sectional dimension. In some embodiments, the first average cross-sectional dimension is less than or equal to about 5000%, less than or equal to about 1000%, less than or equal to about 800%, less than or equal to about 500%, less than or equal to about 400%, less than or equal to about 200%, less than or equal to about 100%, less than or equal to about 90%, less than or equal to about 80%, less than or equal to about 70%, less than or equal to about 50%, less than or equal to about 30%, less than or equal to about 20%, less than or equal to about 15%, less than or equal to about 10%, less than or equal to about 5%, less than or equal to about 2%, less than or equal to about 1%, or less than or equal to about 0.5% greater than the second average cross-sectional dimension. Combinations of the above-referenced ranges are also possible (e.g., the first average cross-sectional dimension is between about 1% and about 5%, between about 10% and about 100%, between about 100% and about 1000%, or between about 1000% and about 5000% greater than the second average cross-sectional dimension).

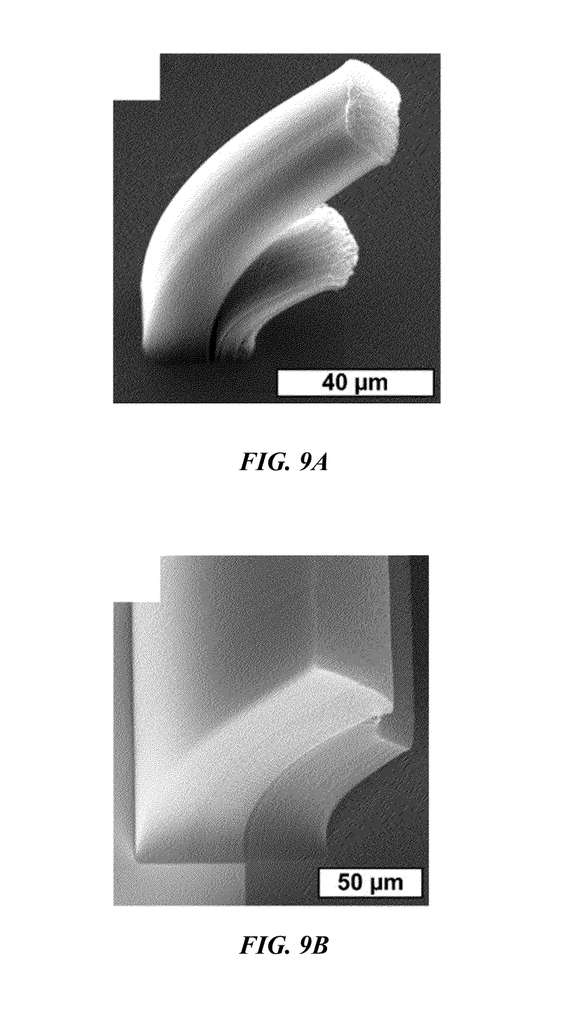

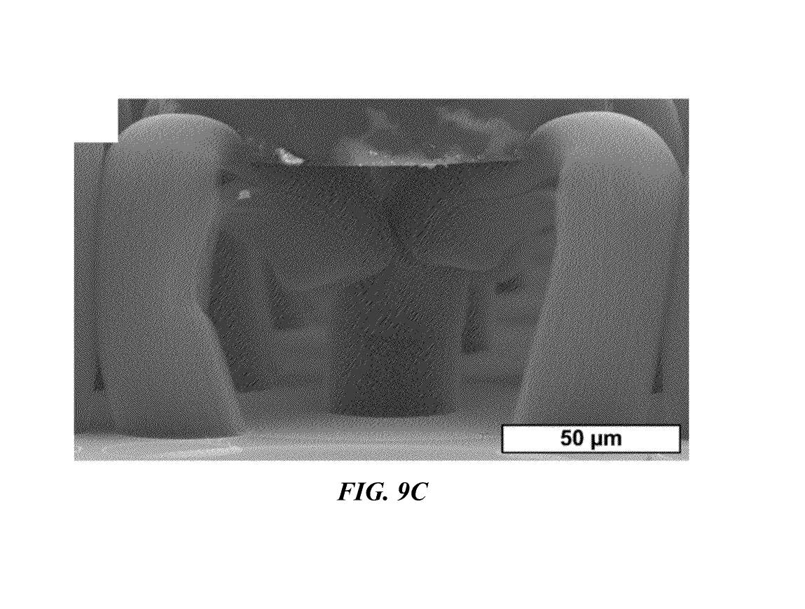

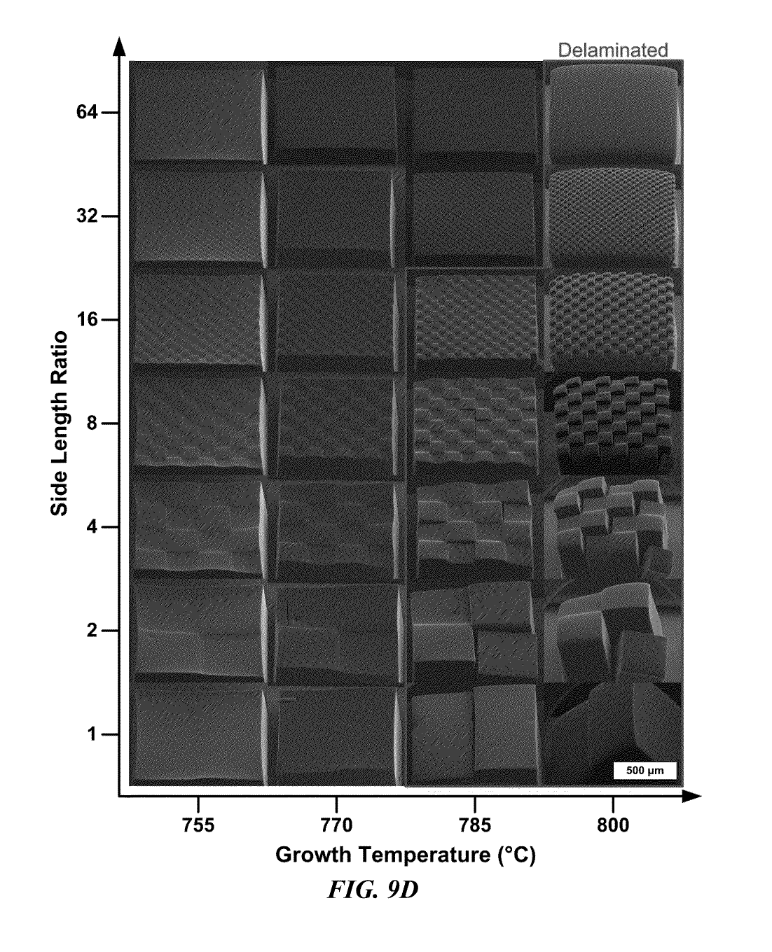

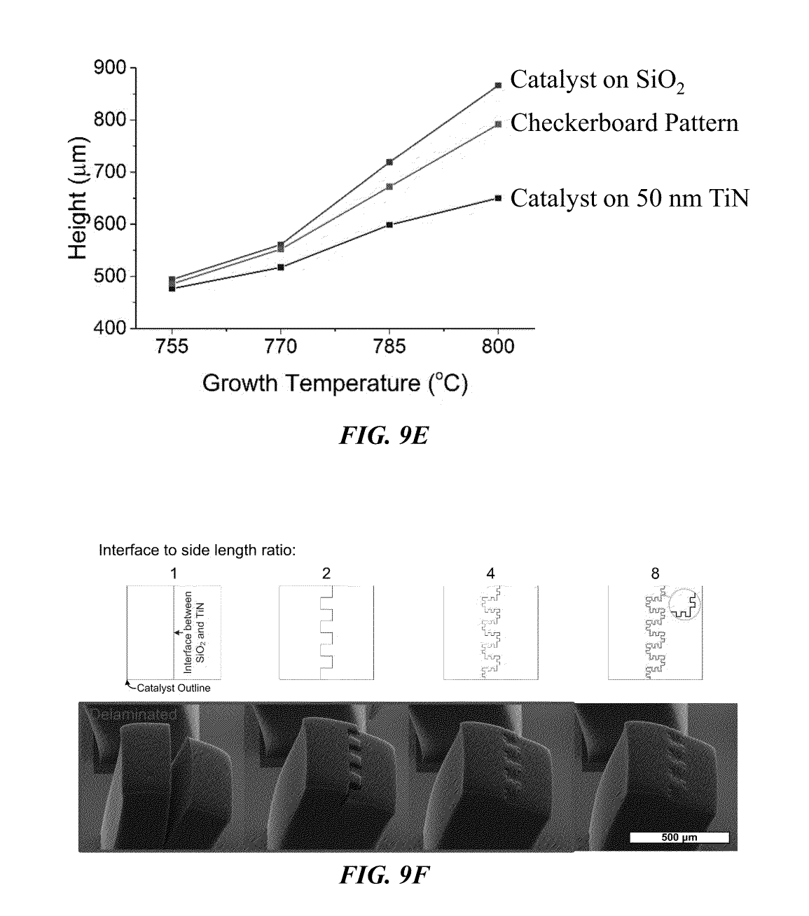

In some embodiments, the one or more microstructures may have different cross-sectional shapes. That is to say, the cross-sectional shape of a first microstructure may be different than the cross-sectional shape of a second microstructure. In some embodiments the cross-sectional shape of the one or more microstructures is a complex shape (e.g., at least a portion of an edge of the shape formed by the microstructure may be non-linear, periodic, or the like). In some cases, a microstructure with a complex cross-sectional shape may offer advantages over microstructures with a simple cross-sectional shape including improved adhesion and/or mechanical coupling between one or more microstructures in contact (see Example 7). For example, an edge of one or more microstructure may be, in some cases, defined by a side length ratio. The side length ratio, as described herein, refers to the ratio of the lengths of a portion of an edge of a first substrate in contact with a portion of an edge of a second substrate (e.g., the ratio of the length of a portion of an edge of a catalyst to the length of a portion of an edge of a substrate comprising TiN in contact with the edge of a catalyst). For example, a side length ratio of about 1 corresponds, in some cases, to a substantially straight interface between a first substrate and a second substrate in contact with the first substrate. In some embodiments, the side length ratio may be between greater than or equal to about 1, greater than or equal to about 2, greater than or equal to about 4, greater than or equal to about 8, greater than or equal to about 16, greater than or equal to about 32, greater than or equal to about 64, greater than or equal to about 128, or greater than or equal to about 256. In certain embodiments, the side length ratio may be less than about 512, less than about 256, less than about 128, less than about 64, less than about 32, less than about 16, less than about 8, less than about 8, or less than about 2. Combinations of the above-referenced ranges are also possible. Non-limiting examples of complex shapes formed as a result of varying values of side length ratios are shown in FIG. 9F.

In some embodiments, at least one portion of the one or more microstructures may be curved. In certain embodiments, the at least one portion of the one or more microstructures has a radius of curvature wherein the curvature is measured by taking a dimension along the axis of the at least one portion of the microstructure, wherein the portion of the microstructure that curves is at least about 5% of the length of the microstructure. Curvature, as will be understood by those skilled in the art, generally refers to a change of angle (e.g., a bend or a series of bends) of a portion of a microstructure in a continuous manner along at least a portion of its length.

Articles and methods comprising two or more microstructures with different properties (e.g., average density, average growth rates, average cross-sectional dimension, mechanical properties, etc.) have several advantages over microstructures fabricated with uniform properties. For example, fabrication of microstructures with different average growth rates may result in a controlled and predictable curvature of the microstructures that would otherwise not be achievable with microstructures fabricated with uniform growth rates. In some embodiments, the structure can have a radius of curvature along at least a portion of its length ranging between about 10 nm and about 10 mm. In certain embodiments, the radius of curvature may be less than or equal to about 10 mm, less than or equal to about 5 mm, less than or equal to about 1 mm, less than or equal to about 500 microns, less than or equal to about 100 microns, less than or equal to about 50 microns, less than or equal to about 10 microns, less than or equal to about 5 microns, less than or equal to about 1 micron, less than or equal to about 500 nm, less than or equal to about 100 nm, less than or equal to about 50 nm, less than or equal to about 10 nm, or less than or equal to about 5 nm. In some embodiments, the radius of curvature may be greater than about 1 nm, greater than about 5 nm, greater than about 10 nm, greater than about 50 nm, greater than about 100 nm, greater than about 500 nm, greater than about 1 micron, greater than about 5 microns, greater than about 10 microns, greater than about 50 microns, greater than about 100 microns, greater than about 500 microns, greater than about 1 mm, or greater than about 5 mm. Combinations of the above-referenced ranges are also possible (e.g., a radius of curvature between about 10 nm and about 100 nm, between about 100 nm and about 1 micron, between about 1 micron and about 10 microns, between about 10 microns and about 100 microns, or between about 100 microns and about 1 mm).

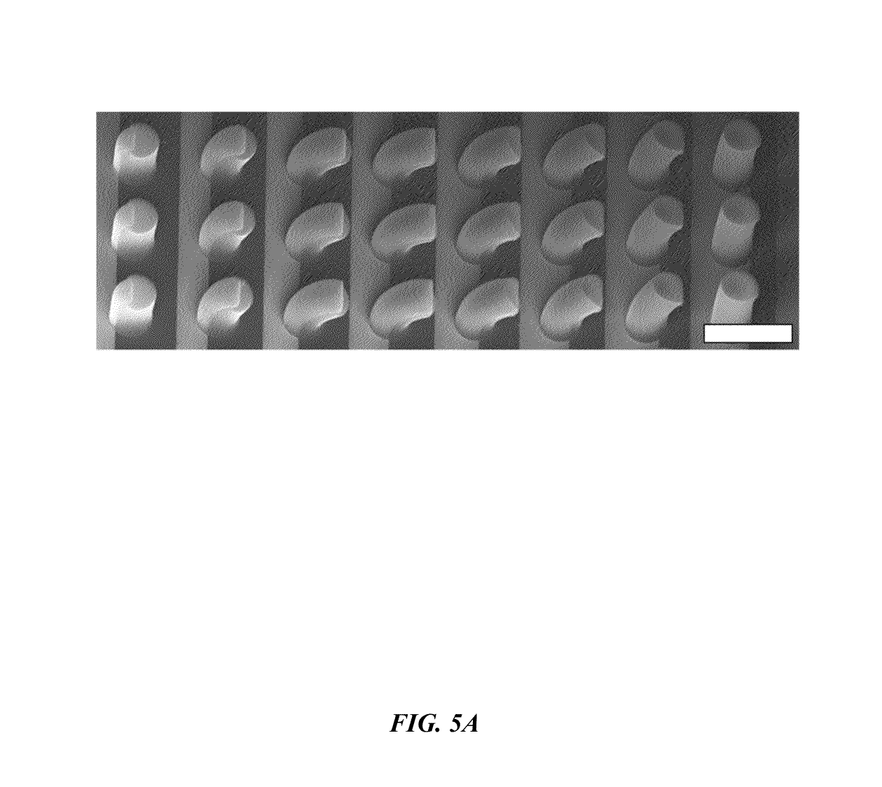

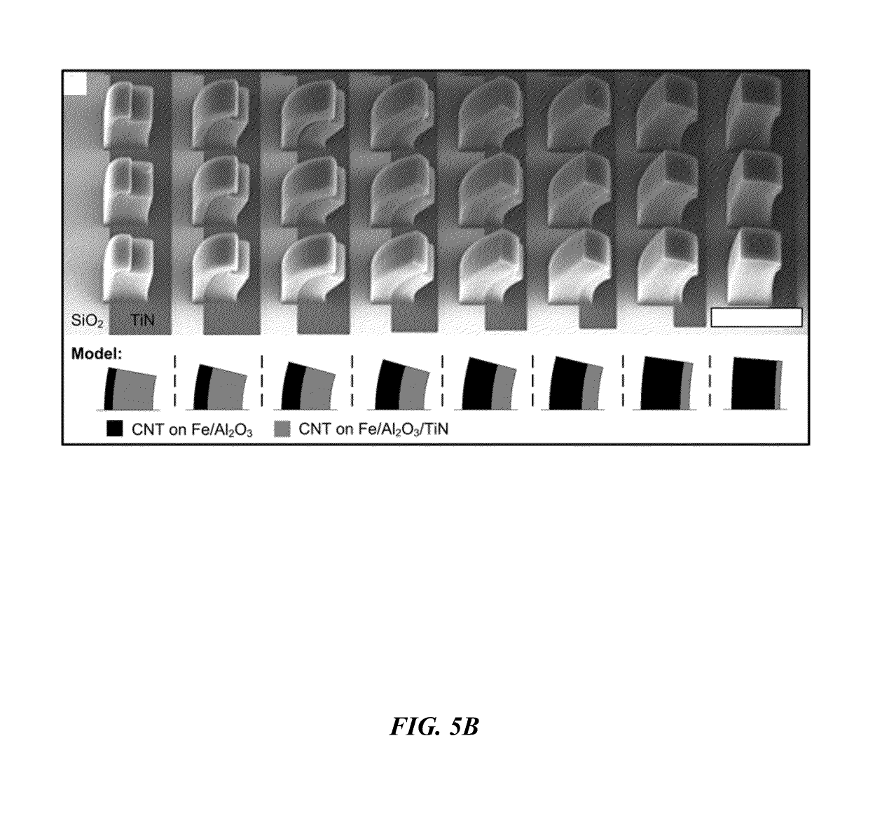

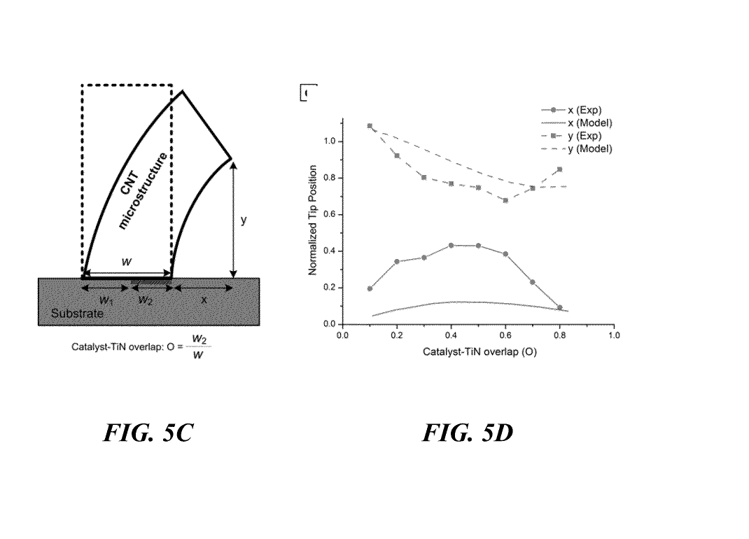

In some embodiments, the curvature of one or more microstructures, as described herein, may be determined as a function of the surface area upon which the one or more microstructures are grown. For example, in some cases, the curvature of the one or more microstructure may be approximated by:

$$\frac{1}{ρ} = \frac{6 ( \frac{{R}_{1} - {R}_{2}}{{R}_{1}} ) {( 1 + m )}^{2}}{w ( 3 {( 1 + m )}^{2} + ( 1 + mn ) ( {m}^{2} + \frac{1}{mn} ) )}$$

wherein ρ is the radius of curvature, R₁ and R₂ are the growth rates (e.g., 1 denotes the growth rate of the first microstructure and 2 denotes the growth rate of the second microstructure), and w is the microstructure width, as illustrated in FIG. 5C. In addition, m and n are defined as

$$m = \frac{{w}_{2}}{{w}_{1}} , n = \frac{{E}_{2}}{{E}_{1}}$$

wherein w denotes the width of the first microstructure and the second microstructure and E denotes the respective Young's Moduli of the microstructures. The ratio of the first growth rate, R₁, to the second growth rate, R₂, is described above.

For example, as illustrated in FIG. 1B, article 100 comprises substrate 110, first microstructure 102 in contact with substrate 110, and second microstructure 104 in contact with the first microstructure and the substrate. In some embodiments, first microstructure 102 has an exposed surface 106. In certain embodiments, second microstructure 104 has an exposed surface 108. Exposed surface 106 and exposed surface 108 may be at an angle (e.g., a tip angle) greater than 0 degrees relative to the substrate, as measured from the distal end of the microstructure. For example, in some cases, the one or more microstructures may have a first surface in contact with and parallel to a substrate and a second surface (e.g., at the distal end) that is exposed and at an angle (e.g., a tip angle) greater than zero degrees, relative to the first surface. Tip angle is a term known to the those of ordinary skill in the art. Tip angle generally refers to the angle formed between the substrate and the portion of the microstructure adjacent the substrate. Exposed surface 106 and exposed surface 108 may be at the same or differing angles relative to substrate 110, as measured from the distal ends of microstructure 102 and microstructure 104, respectively. The angle (e.g., the tip angle) between the exposed surface of the microstructure and the substrate may range, in some cases, between about 0 degrees and about 180 degrees, as measured from the distal end of the microstructure. For example, in some embodiments, the angle (e.g., the tip angle) between the exposed surface and the substrate may be greater than about 0 degrees, greater than or equal to about 10 degrees, greater than or equal to about 20 degrees, greater than or equal to about 30 degrees, greater than or equal to about 40 degrees, greater than or equal to about 50 degrees, greater than or equal to about 60 degrees, greater than or equal to about 70 degrees, greater than or equal to about 80 degrees, greater than or equal to about 90 degrees, greater than or equal to about 100 degrees, greater than or equal to about 110 degrees, greater than or equal to about 120 degrees, greater than or equal to about 130 degrees, greater than or equal to about 140 degrees, greater than or equal to about 150 degrees, greater than or equal to about 160 degrees, or greater than or equal to about 170 degrees, as measured from the distal end of the microstructure. As will be understood by those skilled in the art, the angle and/or curvature of the microstructure is generally due to the differences in properties and the mechanical contact between the two or more microstructures, as described herein.

In some embodiments, the articles and methods described comprise the fabrication of microstructures on one or more substrates. In certain embodiments, two or more microstructures are in contact with two or more substrates. For example, in some embodiments, referring to FIG. 1C, microstructure 102 is in contact with first substrate 120 and microstructure 104 is in contact with second substrate 130. Each substrate, in some cases, may have a particular property (e.g., a catalyst, a reaction site, etc.) that imparts a different growth rate, a different density, a different mechanical property (e.g., Young's elastic modulus) on the microstructure fabricated on the respective microstructures. In some embodiments, the fabrication of one or more microstructures each on the one or more substrates results in the curvature of the one or more microstructures, as described herein. For example, in some cases, microstructure 102 and microstructure 104 comprise the same material, and fabrication of microstructure 102 on substrate 120 results in a higher growth rate of microstructure 102 than fabrication of microstructure 104 on substrate 130, producing curved microstructures.

In certain embodiments, the amount of surface area over which one or more microstructures are fabricated may determine the curvature of the one or more microstructures. For example, referring to FIG. 1D, first microstructure 102 is fabricated on first substrate 120 and second microstructure 104 is fabricated on second substrate 130. The ratio of the surface area of the first substrate on which the first microstructure is fabricated to the surface area of the second substrate on which the second microstructure is fabricated may be greater than or equal to about 1:1, greater than or equal to about 1:1.1, greater than or equal to about 1:2, greater than or equal to about 1:3, greater than or equal to about 1:4, greater than or equal to about 1:5, greater than or equal to about 1:10, greater than or equal to about 1:20, greater than or equal to about 1:50, greater than or equal to about 1:100, greater than or equal to about 1:500, or greater than or equal to about 1:1000.

Certain aspects relate to a method of forming one or more microstructures (or other structures, as noted above). In some embodiments, the method comprises providing one or more substrate portions including one or more reaction sites (e.g., comprising a catalyst material). For example, in some cases, the method comprises providing a first substrate portion including a first reaction site (e.g., a first catalyst material). In certain embodiments, the method comprises providing a second substrate portion adjacent the first substrate portion including a second reaction site (e.g., a second catalyst material). In some embodiments, the method comprises introducing a reaction species (e.g., a precursor material) to the first reaction site. In certain embodiments, the method comprises introducing a reaction species (e.g., a first reaction species and/or a second reaction species) to the second reaction site. In some cases, the method may comprise growing a first microstructure on a first reaction site and a second microstructure on a second reaction site. For example, referring again to FIG. 1D, first substrate 120 may comprise a first reaction site and second substrate 130 may comprise a second reaction site. In some embodiments, introducing the same or differing reaction species to one or more reaction sites results in the curvature of the microstructure fabricated on the one or more reaction sites. In certain embodiments, differences in the one or more reaction sites (e.g., differences in material properties of the one or more substrates) results in the formation of microstructures, as described in more detail below.

Where first and second substrate portions are adjacent, various arrangements are included. In one, two or more substrates are made proximate, thereby defining a single substrate with first and second portions, or more portions, In another, a single substrate has different portions adjacent each other. The different portions can have different functionality (for example, different portions may have a layer to be exposed to microstructure forming conditions), that are different) such that, e.g., each can promote chemical reaction differently (different chemical reasons, or similar or identical chemical reactions in different ways, e.g., at different rates). Substrates are discussed elsewhere herein as well. Other arrangements will be available to those of ordinary skill in the art without undue experimentation.

In some cases, microstructures (e.g., microstructures comprising nanostructures) may be synthesized using the appropriate combination of reaction species and/or catalyst materials. In some embodiments, the reaction species may be delivered sequentially or simultaneously (e.g., as a mixture of reaction species). For example, for the growth of carbon-nanotube based microstructures, suitable precursors include C₂H₄/H₂, CH₄/H₂, CO/H₂, C₂H₂/NH₃, hexane vapor, ethanol vapor, camphor vapor, etc. A variety of growth site materials, support materials (e.g., Al₂O₃, MgO₂), and reactive and non-reactive species may be used based on this knowledge to configure the devices and methods of the present invention to grow and assemble microstructures as desired, and are described in more detail below.

In some cases, the method may involve a chemical vapor deposition process, atomic layer deposition, electroplating, or any suitable chemical deposition process. For example, the method may involve contacting a precursor material (e.g., a reactant vapor) with a catalyst material, and allowing the precursor material (e.g., reactant vapor) to undergo a chemical reaction with the catalyst material to produce a desired product. In some embodiments, gaseous precursor materials, selected for their ability to be converted to a particular desired product, may be introduced directly to a catalyst material in order to form the desired product in high yield and to reduce the formation of potentially harmful and unintended byproducts. For example, a reactant vapor comprising a microstructure and/or nanostructure precursor material may contact a catalyst material (e.g., a metal catalyst material), causing formation of a nanostructure, such as a nanotube. In some embodiments, the reactant vapor may comprise various components, including hydrocarbons (e.g., ethylene), hydrogen, helium, alkyne additives, and other components, as described more fully below.

Upon exposure of the catalyst material to a reactant vapor under a set of conditions selected to facilitate microstructure growth, microstructure may grow from catalyst material. Without wishing to be bound by theory, the mechanism of microstructure formation may involve (1) nucleation, wherein a microstructure precursor material contacts the catalyst material to form nanostructure cap; (2) elongation, where additional microstructure precursor material, such as single carbon units, can add to the growing microstructure by continual dissociation at, diffusion into, and/or precipitation from the catalyst material; and (3) termination, where mechanical stress, catalyst encapsulation, and/or catalyst deactivation may halt microstructure growth.

The one or more substrates may be any material capable of supporting the growth of structures as embraced by the description herein, such as substrates including catalyst materials. Substrates suitable for use in the invention include polymer resins, inorganic materials such as carbon (e.g., graphite), alumina, silicon, metals, alloys, intermetallics, metal oxides, metal nitrides, ceramics, and the like. In some embodiments, the one or more substrates comprise Al₂O₃, TiN, and/or SiO₂. The one or more substrates may be selected to be inert to and/or stable under sets of conditions used in a particular process, such as microstructure growth conditions, nanostructure growth conditions, microstructure removal conditions, and the like. In some cases, the one or more substrates comprise a substantially flat surface. In some cases, the one or more substrates comprise a substantially nonplanar surface. For example, the one or more substrate may comprise a cylindrical surface. In certain embodiments, the one or more substrates comprise a catalyst material. In some embodiments, the substrate may be a particle. Particles may be made from any suitable material. Non-limiting examples of suitable particle materials include iron, nickel, cobalt, molybdenum, or combinations thereof. In some embodiments, the particles may range in diameter between about 1 nm and about 100 nm. Other diameter ranges are also possible. Those skilled in the art will be capable of selecting additional suitable particle materials and/or diameters.

In some embodiments, the one or more substrates may comprise two or more materials (e.g., a first substrate portion and a second substrate portion). For example, in some cases, a first substrate portion may comprise TiN and a second substrate portion adjacent the first substrate portion may comprise SiO₂. In certain embodiments, the one or more substrates and/or substrate portions may be coated with one or more additional materials. For example, in some embodiments, the first substrate portion (e.g., comprising TiN) and the second substrate portion (e.g., comprising SiO₂) are coated with Al₂O₃ and/or Fe.

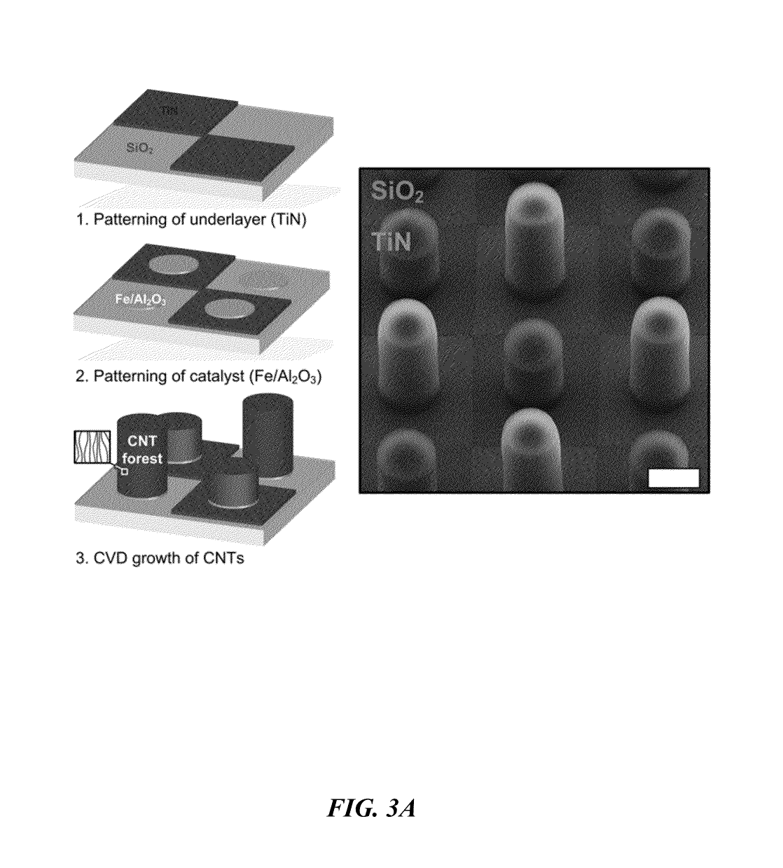

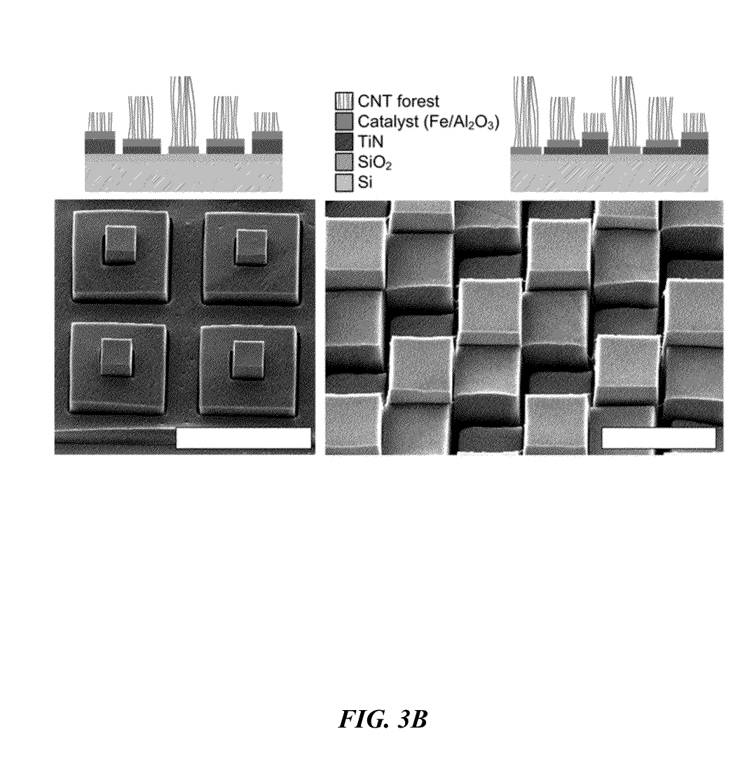

In certain embodiments, the one or more substrates may comprise one or more layers patterned on the substrate. For example, in some embodiments, the substrate comprises a first layer and a second layer patterned on the first layer. The term “patterned” generally refers to regions on a substrate which are alternately coated with a first material and a second material, or alternately coated with a first material and no material. In the illustrative embodiment shown in FIG. 3A, a substrate a first layer of SiO₂ is patterned with a second layer comprising TiN and a third layer patterned on both the SiO₂ and TiN comprising Al₂O₃ and a catalyst material (e.g., iron). Other materials are also possible and selection of such materials would be generally understood by those skilled in the art.

In some cases, it may be desirable to vary the thickness of a substrate and/or a layer on the substrate (e.g., to control the growth rate of a microstructure fabricated on the substrate and/or the layer on the substrate). For example, the ability to control the dimensions of the substrates allows one to control the properties of the microstructures (e.g., the curvature). The thickness of the substrate layer(s) may range between about 1 Angstrom and about 500 nm. For example, in certain embodiments, the thickness of the substrate layer may be greater than or equal to about 1 Angstrom, greater than or equal to about 1 nm, greater than or equal to about 5 nm, greater than or equal to about 10 nm, greater than or equal to about 20 nm, greater than or equal to about 30 nm, greater than or equal to about 40 nm, greater than or equal to about 50 nm, greater than or equal to about 60 nm, greater than or equal to about 70 nm, greater than or equal to about 80 nm, greater than or equal to about 90 nm, greater than or equal to about 100 nm, greater than or equal to about 120 nm, greater than or equal to about 150 nm, greater than or equal to about 200 nm, greater than or equal to about 300 nm, or greater than or equal to about 400 nm. In some embodiments, the thickness of the substrate layer may be less than or equal to about 500 nm, less than or equal to about 400 nm, less than or equal to about 300 nm, less than or equal to about 200 nm, less than or equal to about 150 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, less than or equal to about 20 nm, less than or equal to about 10 nm, less than or equal to about 5 nm, or less than or equal to about 1 nm. Combinations of the above-referenced ranges are also possible.

Methods of the invention may generally comprise formation or growth of microstructures on the surface of a catalyst material (e.g., a substrate comprising a catalyst material). The catalyst material may be any material capable of catalyzing growth of microstructures. In some embodiments, the substrate material described above may be a catalyst material (i.e. capable of catalyzing growth of microstructures). The material may be selected to have high catalytic activity and/or compatibility with a substrate, such that the catalyst material may be deposited or otherwise formed on the surface of the growth substrate. For example, the catalyst material may be selected to have a suitable thermal expansion coefficient as the substrate to reduce or prevent delamination or cracks. The catalyst material may be positioned on or in the surface of the substrate. In some cases, the catalyst material may be formed as a coating or pattern on the surface of the substrate, using known methods such as lithography. In other embodiments, the substrate may be coated or patterned with the catalyst material by contacting at least a portion of the substrate with a solution, film, or tape comprising the catalyst material, or precursor thereof. In some embodiments, the catalyst material may be arranged on or in the surface of a substrate.

Materials suitable for use as the catalyst material include metals, for example, a Group 1-17 metal, a Group 2-14 metal, a Group 8-10 metal, or a combination of one or more of these. Elements from Group 8 that may be used in the present invention may include, for example, iron, ruthenium, or osmium. Elements from Group 9 that may be used in the present invention may include, for example, cobalt, rhenium, or iridium. Elements from Group 10 that may be used in the present invention may include, for example, nickel, palladium, or platinum. In some cases, the catalyst material is iron, cobalt, or nickel. In an illustrative embodiment, the catalyst material may be iron nanoparticles, or precursors thereof, arranged in a pattern on the surface of the growth substrate. The catalyst material may also be other metal-containing species, such as metal oxides, metal nitrides, etc. For example, the catalyst material may be a metal nanoparticle. Those of ordinary skill in the art would be able to select the appropriate catalyst material to suit a particular application.

In certain embodiments, the catalyst material comprises iron, cobalt, or nickel. In some cases, the growth substrate comprises Al₂O₃ and the catalyst material comprises iron. The catalyst material may be formed on the surface of the growth substrate using various methods, including chemical vapor deposition, Langmuir-Blodgett techniques, deposition from a solution of catalyst material, or the like.

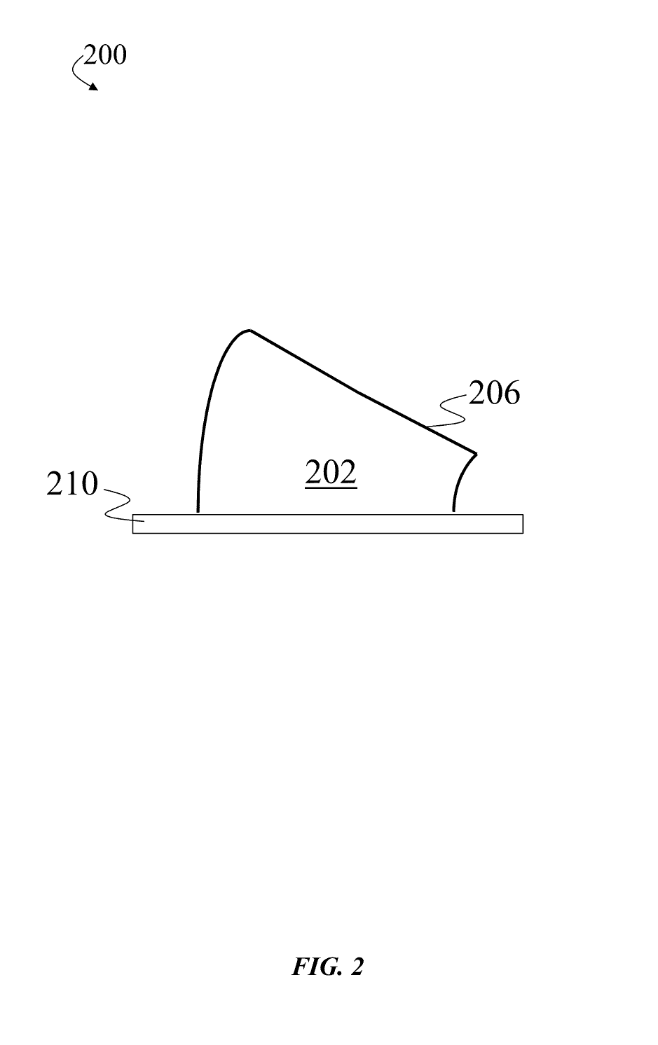

In some cases, the substrate may have a gradient of properties. That is to say, between two or more points on the substrate, the concentration of a material (e.g., the concentration of the catalyst), the thickness of a layer and/or substrate, the size of the catalyst material (e.g., thickness and/or particle size), the composition of the substrate, the composition of the catalyst material, and/or the reaction time varies continuously along a surface of the substrate (e.g., a portion of the substrate). In some cases, the change in substrate properties (e.g., concentration of a material, thickness of the substrate layer and/or substrate, or the reaction time) is discrete (occurring over nanometers, micrometers, millimeters, etc.). In some such embodiments, the resulting microstructure is a single structure with a predictable curvature. For example, referring to FIG. 2, article 200 comprises microstructure 202 fabricated on gradient substrate 210 comprising a gradient of material properties (e.g., thickness, concentration, etc.). In some embodiments, exposed surface 206 of microstructure 202 may be linear and at an angle of greater than zero relative to substrate 210, as described above. In certain embodiments, exposed surface 206 may be substantially non-linear (e.g., curved). In certain embodiments, the change in substrate properties occurs non-linearly along the surface of the substrate (e.g., a portion of the substrate). For example, the change in substrate properties may exhibit a periodicity.

In some embodiments, the one or more microstructures may be coated with any suitable material to enhance a variety of properties (e.g., mechanical properties). Non-limiting examples of suitable coatings include substrate materials (e.g., Al₂O₃), metals, metal oxides, and polymers.

The fabrication of microstructures as described above offers several advantages over traditional microstructure fabrication methods. For example, in some cases, due to the local interaction and differential growth rate determining the trajectory of each microstructure, large arrays with nearly identical anisotropic shapes may be produced. In some embodiments, the methods described herein require only two steps (e.g., preparation of the substrate and addition of a reaction species), as compared to more expensive and complicated traditional fabrication methods requiring numerous serial iterations. In certain embodiments, the capability to produce such microstructures using only 2D patterning methods along with standard thermal processing contrasts the limitations of many existing processes that require serial processing or sequential exposure using complex inclined lithography methods. For example, this represents a highly attractive principle for materials design, and offers a method for scalable manufacturing of 3D microstructured surfaces having biomimetic properties.

Yet another advantage of the methods described herein includes enabling the direct synthesis of complex microstructures that are perpendicular, rather than parallel, to the substrate as compared to typical subtractive etching and release techniques practiced in the art. In some embodiments, the fabrication of closely packed arrays of structures with heterogeneous shapes, and the porosity of the microstructures (e.g., comprising nanotube forest)s enables conformal coating after growth to modify chemical and/or mechanical properties.

The microstructures described herein can be incorporated into a variety of surfaces and/or substrates for use in various applications including applications which require modification of a surfaces' adhesion, wettability, or mechanical properties. For example, the microstructures described herein may be suitable for applications in which surfaces require high rates of heat transfer. In some embodiments, the microstructures may alter the mechanical properties of a surface (e.g., increasing the Young's elastic modulus of a surface). In certain embodiments, the microstructures may increase the lamination between one or more substrates comprising the microstructures (e.g., stacked layers comprising microstructures, adjacent sheets comprising microstructures). In some embodiments, the microstructures described herein may be used as a dry adhesive (e.g., entangling with microstructures on an adjacent substrate, electrostatic interaction with an adjacent substrate, etc.)

During use, the microstructures described herein may alter the condensation, evaporation, and/or boiling of a fluid on a surface comprising the microstructures. In some embodiments, the addition of microstructures to a surface or substrate alters the way a fluid flows across the surface (e.g., the wettability of the surface or substrate). For example, the formation of microstructures on a substrate may enable the ability to control fluid flow across the substrate (e.g., through curvature and/or patterning of microstructures). In some cases, the microstructures described herein may be used in active surfaces (i.e. surfaces which respond to external stimuli). For example, the microstructures may change shape in response to an electrical, chemical, or mechanical stimulus. In some embodiments, the microstructures may be used to form electrical contacts (e.g., wherein the microstructures comprise an electrically conductive material). For example, the microstructure may be able to change shape (e.g., in response to an electrical stimulus) to activate an electrical switch.

In certain embodiments, the microstructures described herein may be incorporated for use in a sensor. For example, the microstructures may be functionalized with a material that is capable of interacting with an analyte. In some embodiments, functionalized microstructures may be incorporated into an electrical circuit (e.g., as described above) to enable sensing of an analyte.

Microstructures are described herein as primary examples of structures fabricated in accordance with the invention. As noted above, structures of dimentions different thatn mictusturctures can also be fabricated taking advantage of the teachings of the invention. It is also to be understood that the invention lies also in shapes and other properties of components that make up those structures, e.g., nanostructures that together define microstructures. For example, nanostructures such as nanotubes are described herein which are grown on different portions of a substrate (or different substrates), in proximity to each other sufficient such that the different growth properties of the nanotubes affect the overall properties of the microstructure structure they define. Where that overall structure is a microstructure that is curved or the like, it is to be understood that this invention includes the underlying nanostructures which themselves are also curved, or the like.

### Examples

The following examples illustrate embodiments of certain aspects of the invention. It should be understood that the processes described herein may be modified and/or scaled for operation in a large batch or a continuous fashion, as known to those of ordinary skill in the art.

### Example 1

The following example describes a general procedure for microstructure synthesis.

Catalyst and TiN layers were patterned on (100) silicon wafers with 300 nm of thermally grown SiO₂. Each layer was patterned by lift-off processing, by photolithography (photoresist IX845) followed by ultrasonic agitation in acetone. The TiN layer was deposited and patterned first, and then the catalyst layer (1 nm Fe upon 10 nm Al₂O₃) was deposited and patterned. The wafer was then cut into ˜1×1 cm pieces, and the substrates were placed in a quartz tube furnace, and the CNT growth was performed.

The recipe started by with flowing 100/400 sccm of He/H₂ while heating to 775° C. over 10 minutes (ramping step); then the system was held at 775° C. for 10 minutes (annealing step) while maintaining the gas flow. Then 100 sccm of C₂H₄ was added to the gas mixture at 775° C. for CNT growth for the desired duration. The typical growth rate was ˜50 μm/minute on Fe/Al₂O₃/SiO₂. Once the CNTs have grown, C₂H₄ was removed from the gas mixture and the furnace was cooled to <100° C. After cooling, the system was purged with He before the sample was removed. Optionally, C₂H₄ flow can be maintained while cooling down to improve the adhesion of the CNT microstructures to the substrate. Once the cooling step was complete, the quartz tube was purged with 1000 sccm of He for 5 minutes before opening up the end caps and retrieving the samples.

To characterize the CNT microstructures, small angle x-ray scattering (SAXS) was used comprising a G1 beamline (10±0.1 keV, 0.13 nm wavelength). The beam was focused to a 10 μm spot using a single bounce monocapillary. The CNT sample was placed on a motorized stage and the focused X-ray beam was passed through the sample. The scattered beam was collected using a 2D detector and the measured intensities were normalized to the original intensity measured by another detector at upstream of the CNT sample. The scattering data was then fitted to a mathematical model assuming a log-normal distribution of hollow cylinders to calculate the CNT diameters as well as the Herman's parameter for CNT alignment.

### Example 2

The following example describes the formation of microstructures with different growth rates via substrate patterning.

Patterning of CNT growth catalyst (Fe/Al₂O₃) on a SiO₂/TiN “checkerboard” followed by exposure to standard CVD conditions (see Example 1) resulted in a “bi-level” CNT micropillar array (FIG. 3A). The catalyst patterns directly on SiO₂ grew CNTs to ˜100 μm (in <2 minutes), whereas the patterns on TiN (upon SiO₂) grew CNTs to 50 μm in the same time span. As shown in FIG. 3B, “tri-level” CNT forests were grown by arranging patches of catalyst on SiO₂, 70 nm TiN, and 140 nm TiN. This principle could be extended to an arbitrary number of levels or even continuous height gradients via additional lithography and underlayer deposition steps that modulate the growth rate via catalyst-substrate interactions.

### Example 3

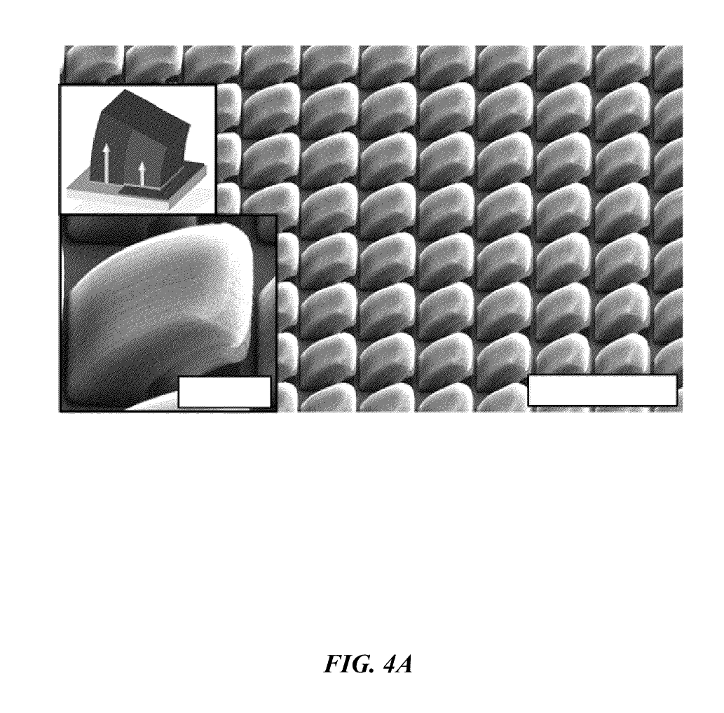

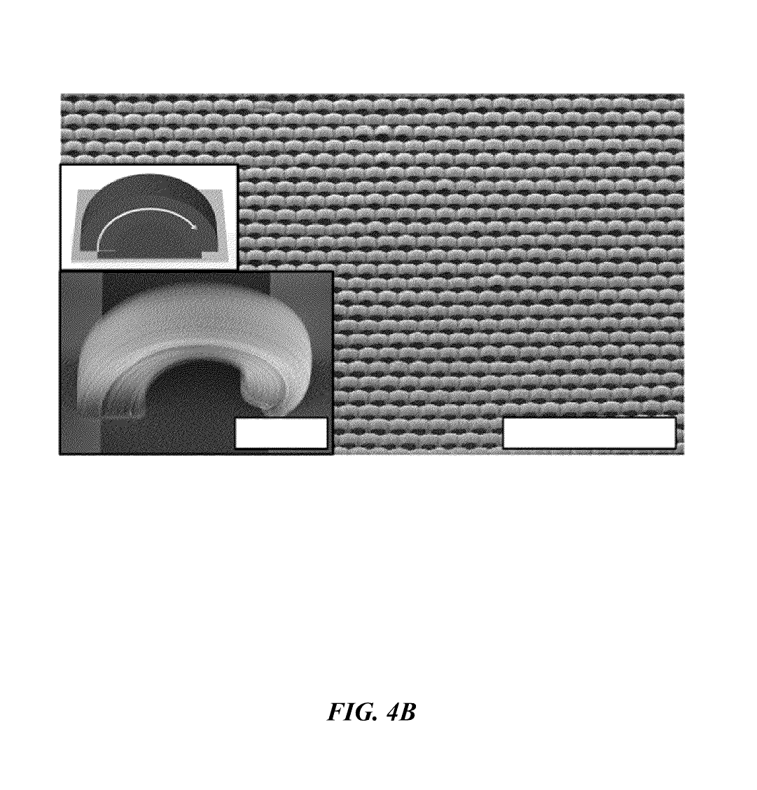

The following example describes the use of the differential growth principle (see Example 2) to design a compound catalyst/underlayer pattern that directly formed curved CNT forest geometries. When a continuous micro-scale catalyst pattern was placed partially on SiO₂ and partially on TiN, the differential growth rates induced stress within the CNT microstructure. For example, as shown in FIG. 4A and FIG. 4B, a square catalyst pattern with half of its area on the TiN layer bent towards the side which is upon TiN, due to the difference in growth rate on the coupled halves of the structure. The stress was transferred between contacting CNTs at the boundary region via mechanical entanglement and van der Waals interactions among the CNTs. Depending on the curvature and length of the structures, slanted micropillars (FIG. 4A), or arches (FIG. 4B) were fabricated. Due to the local interaction and differential growth rate determining the trajectory of each structure, large arrays with nearly identical anisotropic shapes were produced as shown in the SEM images. Importantly, these 3D structures were fabricated using only two standard photolithography steps, one for patterning the TiN layer, and one for patterning the catalyst layer.

### Example 4

The following example demonstrates control of the curvature of the microstructure by designing the amount of overlap between the catalyst and the substrate. FIGS. 5A and 5B show arrays of round and square cross-section micropillars, respectively, where the overlap distance was varied from left to right (at increments of 5 μm). The portion of the pillars growing on TiN was always shorter, and as a result, all pillars bent towards the TiN side. As the portion of overlap decreased, the stress induced by the differential growth rate caused increased bending (i.e. a smaller radius of curvature), reaching a maximum when the catalyst shape was split symmetrically by the TiN layer. With <50% overlap on TiN, the curvature increased gradually until the structure was only slightly curved at the rightmost extent of the array. The CNTs were generally tangential to the curvature of the microstructures, similar to the CNT alignment observed in CNT forests.

### Static Model of Stress-Driven CNT Curvature.

The curvature of the compound CNT microstructure was described as:

$$\frac{1}{ρ} = \frac{6 ( \frac{{R}_{1} - {R}_{2}}{{R}_{1}} ) {( 1 + m )}^{2}}{w ( 3 {( 1 + m )}^{2} + ( 1 + mn ) ( {m}^{2} + \frac{1}{mn} ) )}$$

wherein ρ is the radius of curvature, R₁ and R₂ are the growth rates (e.g., 1 denotes CNTs on Fe/Al₂O₃/SiO₂ and 2 denotes CNTs on Fe//Al₂O₃/TiN), and w is the CNT micropillar width. In addition, m and n are defined as

$$m = \frac{{w}_{2}}{{w}_{1}} , n = \frac{{E}_{2}}{{E}_{1}}$$

wherein w denotes the width and E denotes the respective Young's Moduli of the segments. The value of n is specified as 0.6 which is the ratio of the measured areal mass density of CNTs on the respective underlayers; however, because the elongation of each layer is specified in the model, the output is insensitive to this value. The geometric parameters are illustrated in FIG. 5C.

Using the calculated curvatures, and the weighted average growth rate, the shapes of the resultant CNT microstructures were visualized using MATLAB®. The simulation results (FIG. 5D) corresponded to the rows of structures in the SEM image FIG. 5B. To compare the experiments to the simulation, the tip position was characterized in horizontal and vertical axes, normalized to the base dimension (w), as shown in FIG. 5C. As shown in the graph in FIG. 5D, for both the experiment and simulation, the x position of the tip reached its maximum at 0.4 overlap, and the y position reached its minimum at approximately 0.6-0.7 overlap.

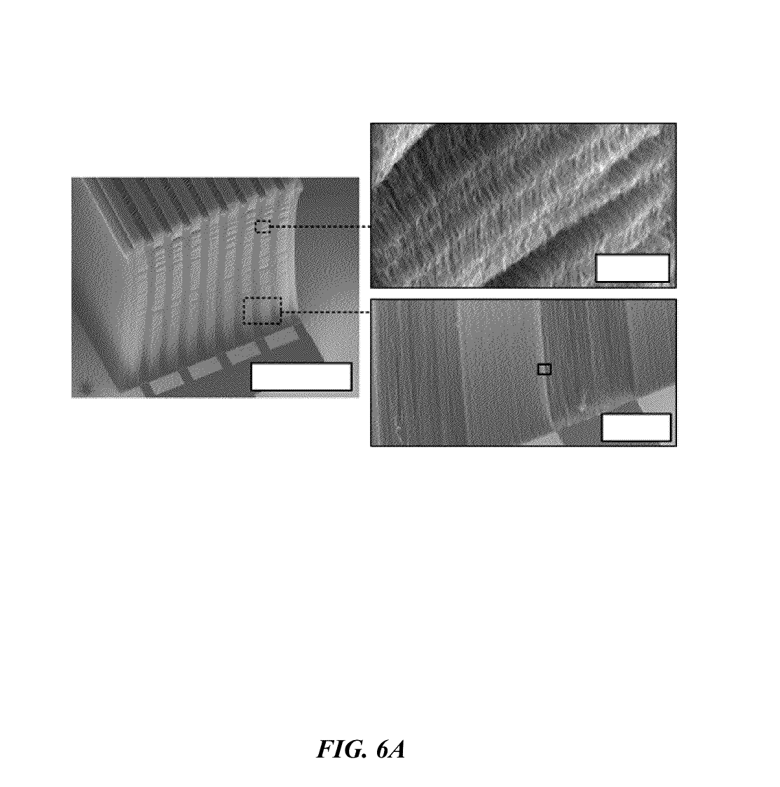

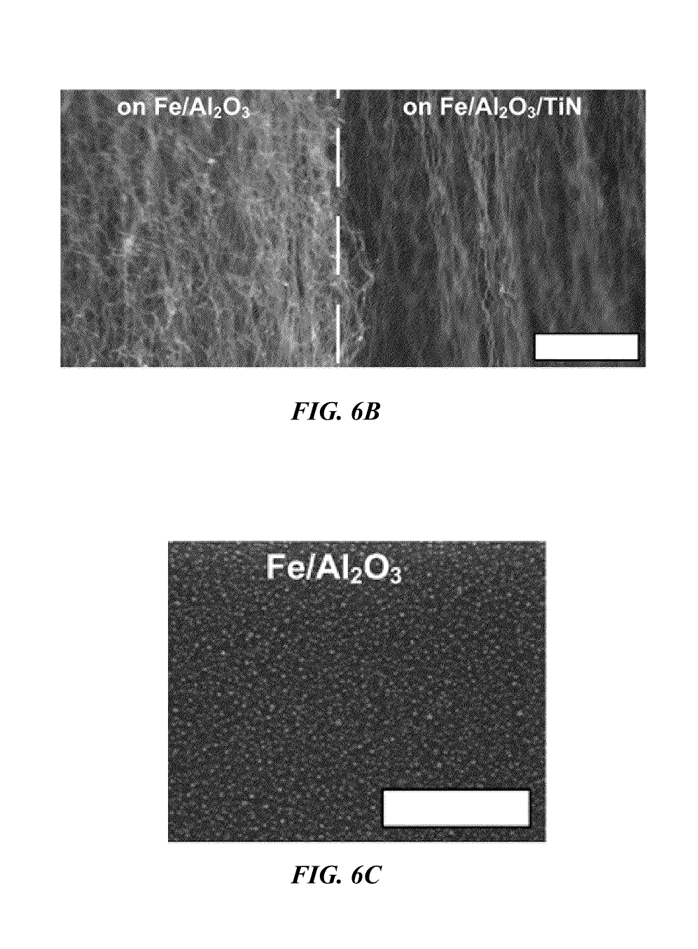

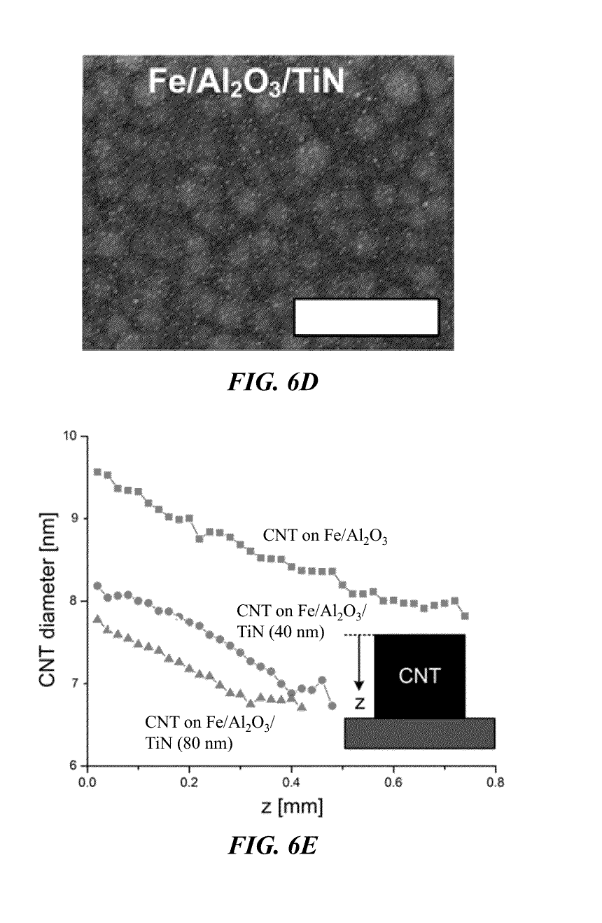

To gain further insight into the mechanical coupling causing stress-driven bending, a “striped” structure was designed where alternate catalyst/underlayer regions are coupled with a large interfacial area (FIG. 6A). This structure is symmetric, so it grows straight vertically yet has significant internal stresses. As shown in FIGS. 6A-6E, the faster growing CNTs deformed collectively into a wavelike pattern. Therefore, while the vertical growth rate of the structure was matched at the interface, the faster growing side still accumulated longer CNTs and these CNTs bent and possibly buckled to accommodate their additional length. This deformation mode is similar to what is observed in mechanically compressed forests.

The strain-engineered CNT microstructures showed differing CNT density and alignment in the fast and slow growing portions. In FIGS. 6A-B, the CNTs grown from catalyst on TiN appeared to have greater vertical alignment influenced by the interface with the faster-growing region. On the other hand, the CNTs grown from catalyst on SiO₂ were less aligned, due to the retarding force from the slower-growing mating regions.

Small Angle X-ray Scattering (SAXS) was used to further investigate the CNT forest morphology. For this experiment, CNTs were grown for 10 minutes on SiO₂, and on 40 nm, and 80 nm TiN layers; these samples reached lengths of 800, 500, and 400 μm respectively. The scattered X-ray intensities were fitted to a mathematical form factor model for hollow cylinders to calculate the diameter and Herman's orientation parameter, which is a measure of alignment. Both the CNT diameter (FIG. 6E) and alignment are shown to be lesser for increasing TiN underlayer thickness. Specifically, CNTs on SiO₂ had an initial average diameter of 9.5 nm, while CNTs on TiN were approximately 8 nm in diameter.

The Herman's orientation parameter increased from the top of the forest (the initial growth), then reached a maximum, and then decreased toward the bottom of the forest. This trend was typically observed for CNT forests grown by CVD, and has been attributed to density variation due to collective activation and deactivation of the growing CNT population. The measured areal mass density of the CNT forests was 0.011 mg mm⁻² on 80 nm TiN and 0.018 mg mm⁻² on SiO₂. Therefore, these methods showed that placement of the TiN layer under the catalyst results in CNT forests with a smaller average CNT diameter, lesser alignment of CNTs, and a lower density.

### Example 5

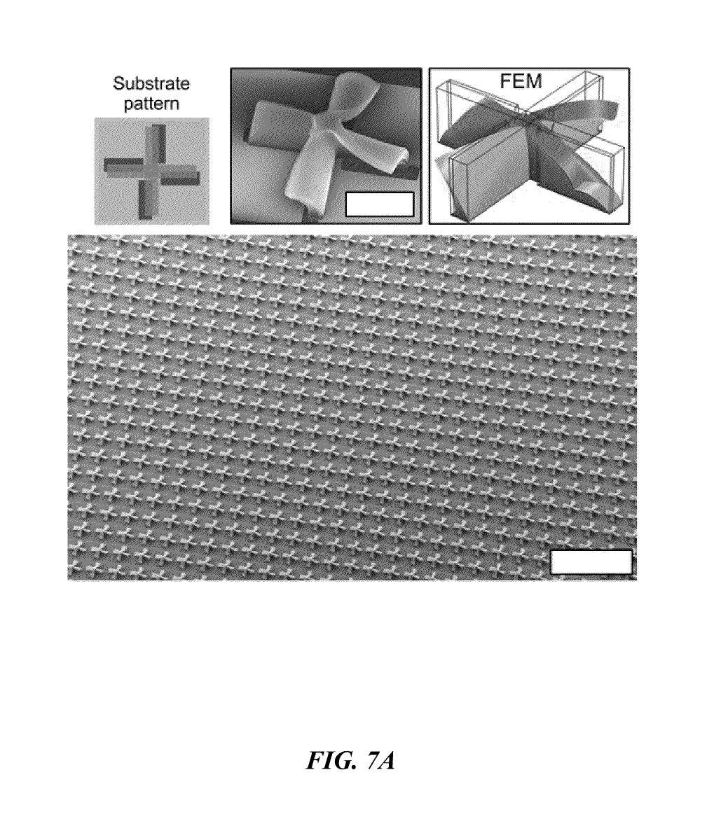

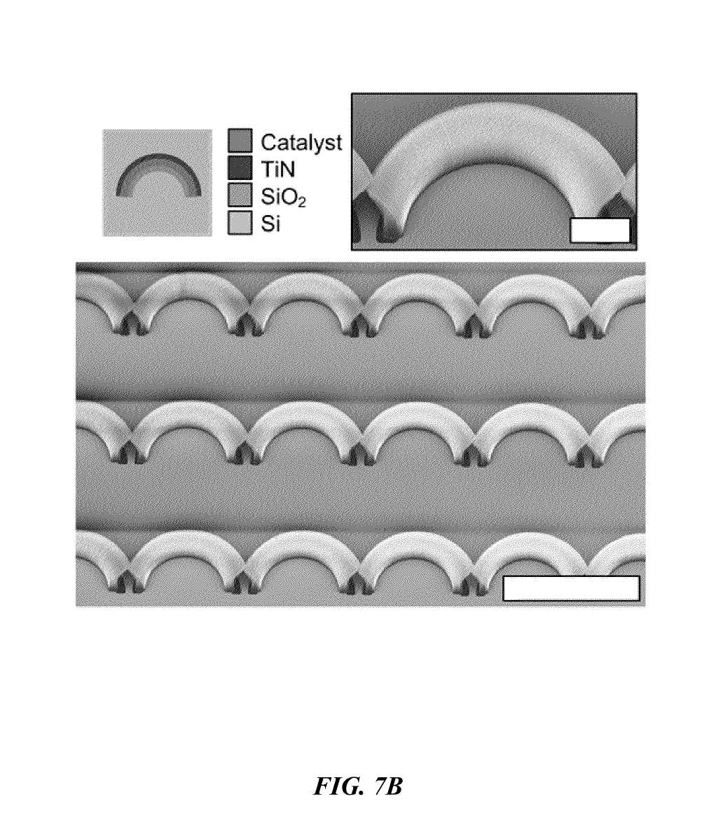

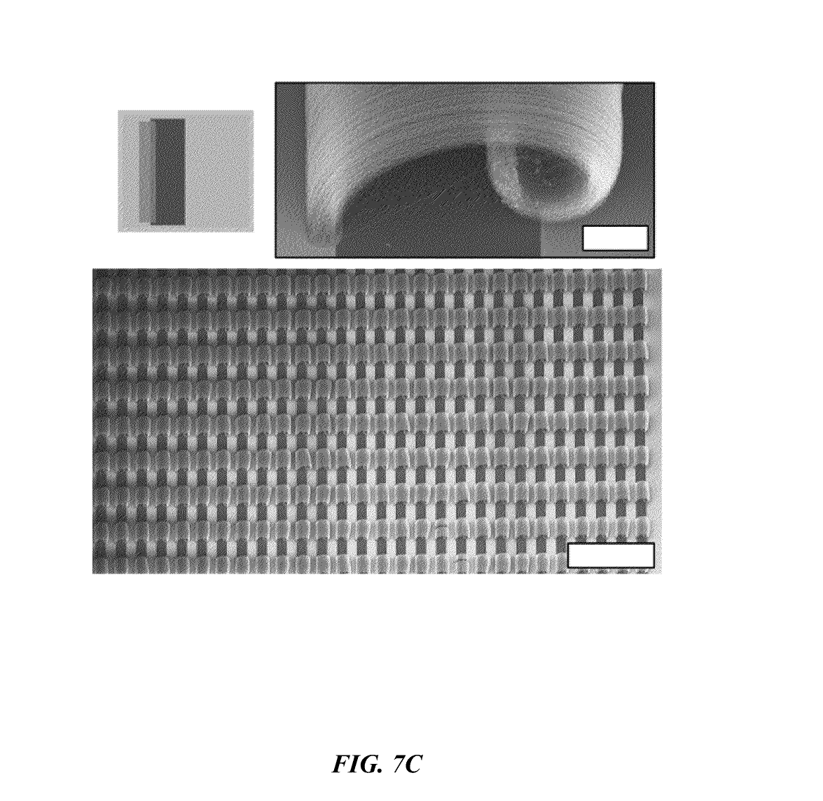

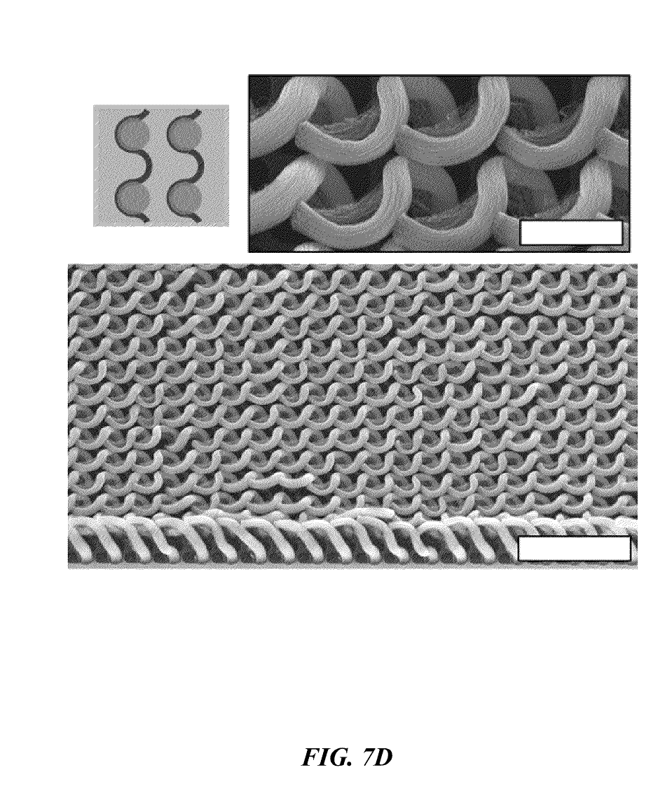

This example demonstrates the design of more complex patterns to produce exemplary microstructures having complex curvature. For example, a compound shape consisting of a “+” catalyst microfeature with each arm offset by a rectangular TiN underlayer resulted in growth of twisted CNT microstructures (FIG. 7A), resembling macroscale propellers. Similarly, thin semicircles of CNTs were directed to curve outward by offsetting the TiN underlayer as shown in FIG. 7B. Further structural complexity was shown by the scrolling of thin offset rectangular patterns (FIG. 7C). Last, exotic hierarchical arrangements were formed by the interaction of closely spaced structures, such as the self-organization of offset circular micropillars into wavy patterns (FIG. 7D) that are reminiscent of macroscale crochet stitching.

Notably, in spite of the complex geometries and local deformations, all of these structures were produced with reliable consistency over large arrays. Arrays of several hundred structures were examined and shown to exhibit nearly identical forms, with defects most frequently arising from debris due to the lithography process rather than the CNT growth step.

### Example 6

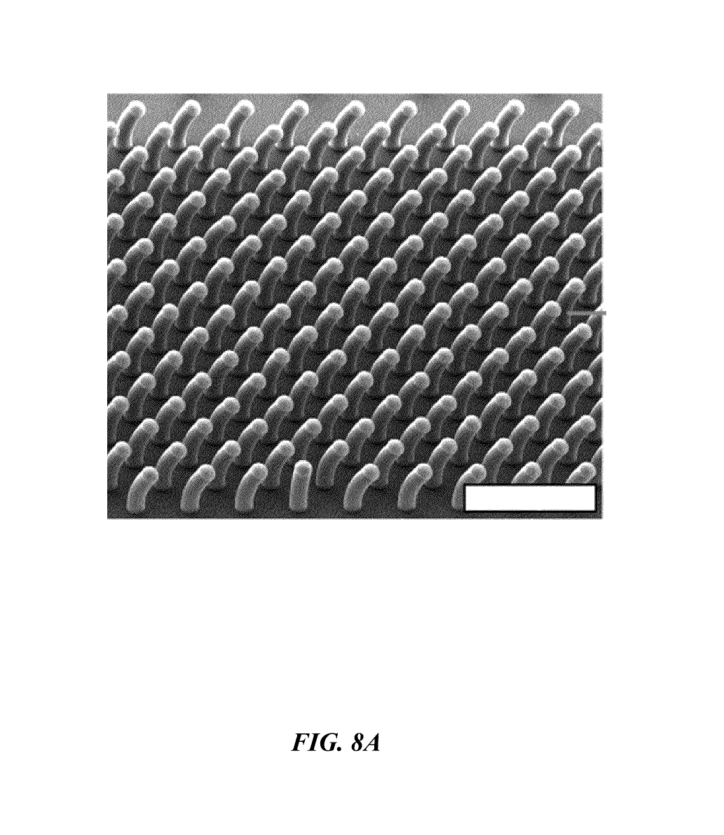

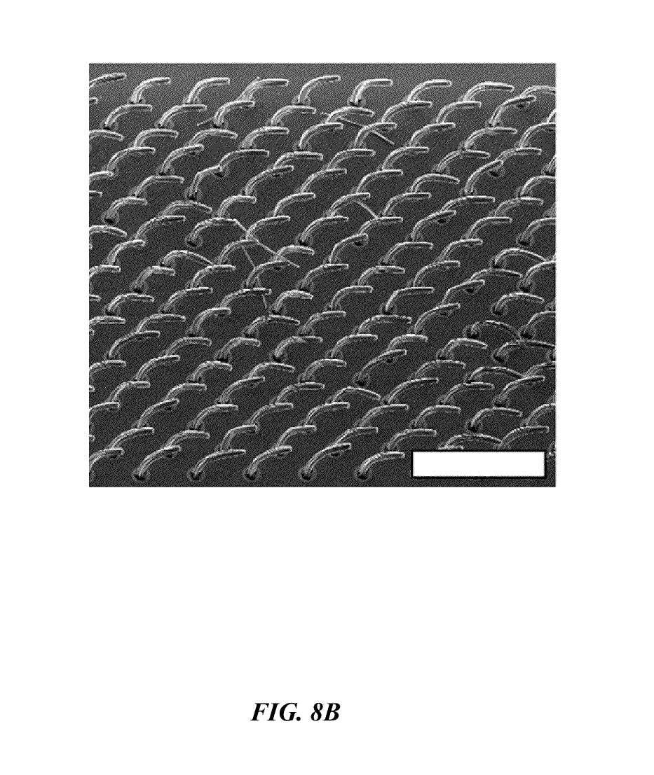

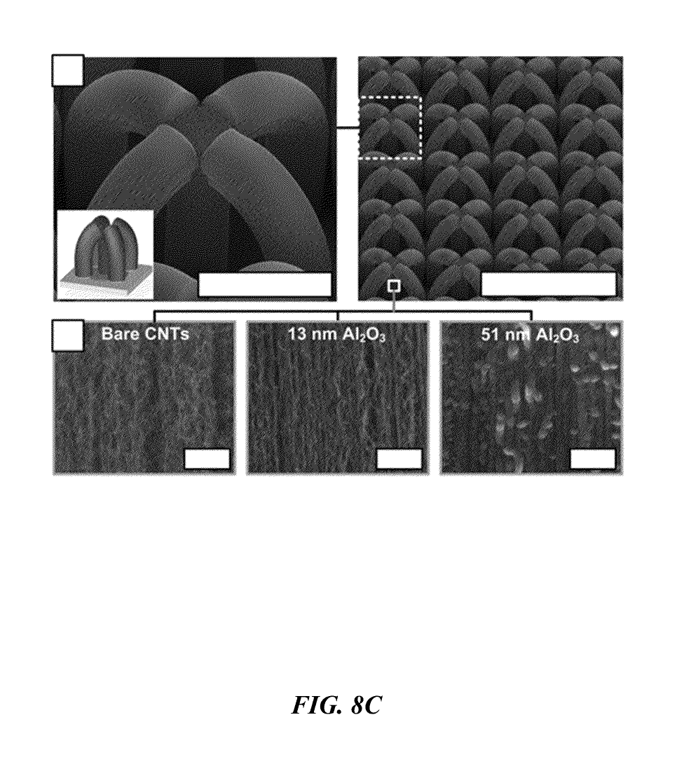

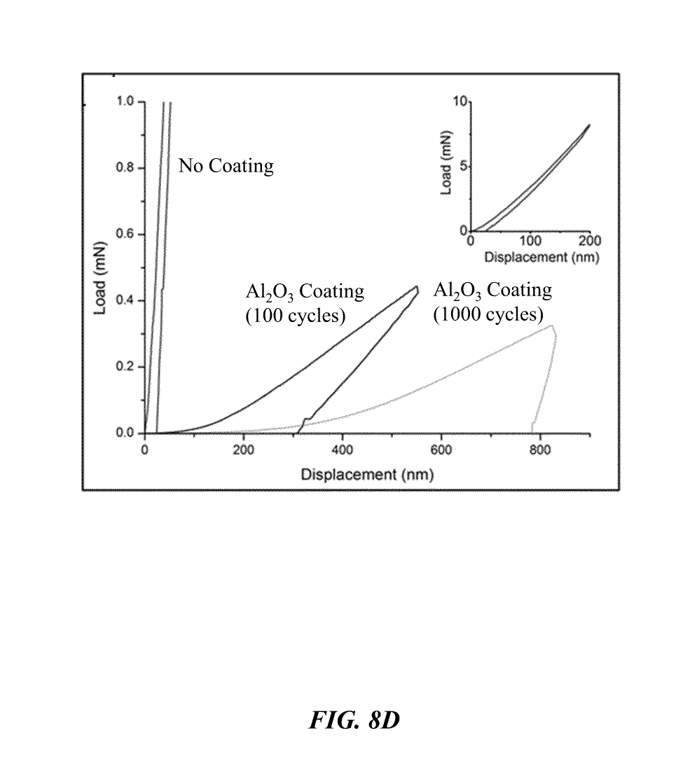

This example demonstrates the processing of complex microstructures via both wet and dry methods that enabled tuning of their properties and functionality. Low-density bent CNT micropillars were transformed into robust densely packed CNT structures by capillary forming (FIG. 8A-8B). The substrate was exposed to a stream of heated acetone vapor, causing acetone to condense onto the CNTs and substrate, and infiltrate each CNT microstructure. Upon subsequent evaporation of the acetone, the CNT forest shrank laterally.

Alternatively, curved CNT microstructures were coated conformally via vapor phase methods, thereby enabling decoupled control of geometry and mechanical properties. CNT “microtruss arrays” (FIGS. 8C-8E), were fabricated, analogous to truss designs used in composite materials to achieve high strength and energy absorption at relatively low density. The CNT microtrusses each consisted of four corner members and a central pillar, meeting at an apex. The CNT microtrusses were coated with both parylene (by chemical vapor deposition, CVD) and alumina (by atomic layer deposition, ALD, FIG. 8D). Upon vapor phase infiltration of the precursors, the CNTs and bundles within the forest were coated individually and conformally, enabling fine-tuning of their porosity and mechanics without altering the microstructure geometry. Via flat punch compression testing, a 51 nm Al2O3 coating on the CNTs increased the mechanical stiffness by more than 100-fold; typical loading-unloading curves are shown in FIG. 8E for different coating materials and thicknesses. The equivalent stiffness range of the 3D CNT microtrusses was 0.36 to 54 kN m⁻¹, which spans typical values of MEMS springs used in probe card arrays.

### Example 7

This example demonstrates the use of microstructures with complex shapes and/or edges to control curvature.

During growth of some microstructures, as described above, one or more microstructures was subject to both axial stress parallel to the CNT axis and shear stress transferred through the interface. When there was substantial growth rate mismatch between the segments, the shear stress overcame the interfacial strength and caused the segments to delaminate (FIG. 9A). The stress parallel to the CNT axis can either be tensile or compressive, depending on the relative growth rates, and resulted in local buckling of the CNTs in the faster-growing segments as they are subject to compressive stresses (FIG. 9B). CNTs are much stiffer in tension, hence the counterparts in the neighboring segments did not fail. Structures that had not delaminated nor undergone local buckling of CNTs still carried residual stresses, which caused them to delaminate (FIG. 9C) and/or buckle upon loading which intensifies these stresses.

By increasing the length of the interface between the fast and slow growing portions, the delamination of the structures was prevented. For example, checkerboard patterns with alternating TiN (50 nm) and SiO₂ underlayers below large catalyst patterns (1024 μm by 1024 μm) were fabricated as shown in FIG. 9D. The side length ratio is defined as the ratio of catalyst pattern side length and TiN square side length, and was varied at 1, 2, 4, 8, 16, 32, and 64. The larger this ratio, the longer the length of the interface. The checkerboard patterns were grown for 5 minutes at 755, 770, 785, and 800° C. It was shown that the compound checkerboard patterns grew to an intermediate height between the two separate structures on SiO₂ and TiN (FIG. 9E), and grew to dcloser heights to the structures on SiO₂. As the growth temperature increases, the relative growth rate ratio of CNTs on Fe/Al₂O₃ and Fe/Al₂O₃/TiN decreased, leading to increased shear stress at the interface. Checkerboard structures grown at 755 and 770° C. did not delaminate regardless of the side length ratio, whereas those grown at 800° C. delaminated even at the highest side length ratio. Those grown at 785° C. delaminated when the side length ratio was 16 or less. This confirmed that longer interface length may indeed lower the shear stress at the interface, and hence prevent delamination. For a given straight interface, a fractal design can be implemented to increase the interface length to prevent delamination as shown in FIG. 9F.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed:

1. An article, comprising:
a substrate;
a first microstructure adjacent the substrate;
a second microstructure adjacent the first microstructure,
wherein the first microstructure has a greater average density, greater average cross-sectional dimension, greater average growth rate, and/or different chemical composition than the second microstructure; and
wherein the first structure has a appreciably non-zero tip angle relative to the vertical when measured at the distal end of the first microstructure.

2. An article according to claim 1, wherein the first microstructure and/or second microstructure comprises at least one material selected from the group consisting of nanotubes, nanowires, nanofibers, polymers, metals, ceramic, and biomolecules.

3. An article according to claim 1, wherein the nanotubes are carbon nanotubes.

4. An article according to claim 1, wherein the carbon nanotubes are single-walled carbon nanotubes.

5. An article according to claim 1, wherein the carbon nanotubes are multi-walled carbon nanotubes.

6. An article according to claim 1, wherein the carbon nanotubes have a diameter of less than 100 nm.

7. An article according to claim 1, wherein the first structure is in contact with the second structure.

8. An article according to claim 1, wherein the first structure and the second structure are mechanically coupled.

9. An article according to claim 1, wherein the tip angle can be controlled by changing the first average growth rate and/or the second average growth rate.

10. An article according to claim 1, wherein the average growth rate of the first microstructure is at least about 1% greater than the average growth rate of the second microstructure.

11. An article according to claim 1, wherein the average growth rate of the first microstructure is at least about 10% greater than the average growth rate of the second microstructure.

12. An article according to claim 1, wherein the average growth rate of the first microstructure is at least about 100% greater than the average growth rate of the second microstructure.

13. An article according to claim 1, wherein the average growth rate of the first microstructure is at least about 1000% greater than the average growth rate of the second microstructure.

14. An article according to claim 1, wherein the average density of the first microstructure is at least about 1% greater than the average density of the second microstructure.

15. An article according to claim 1, wherein the average density of the first microstructure is at least about 10% greater than the average density of the second microstructure.

16. An article according to claim 1, wherein the average density of the first microstructure is at least about 100% greater than the average density of the second microstructure.

17. An article according to claim 1, wherein the average density of the first microstructure is at least about 1000% greater than the average density of the second microstructure.

18. An article according to claim 1, wherein the average cross-sectional dimension of the first microstructure is at least about 1% greater than the average cross-sectional dimension of the second microstructure.

19. An article according to claim 1, wherein the average cross-sectional dimension of the first microstructure is at least about 10% greater than the average cross-sectional dimension of the second microstructure.

20. An article according to claim 1, wherein the average cross-sectional dimension of the first microstructure is at least about 100% greater than the average cross-sectional dimension of the second microstructure.

21. An article according to claim 1, wherein the average cross-sectional dimension of the first microstructure is at least about 1000% greater than the average cross-sectional dimension of the second microstructure.

22. An article according to claim 1, wherein the first substrate comprises at least one of the group consisting of TiN, SiO₂, and Al₂O₃.

23. An article according to claim 1, wherein the second substrate comprises at least one of the group consisting of TiN, SiO₂, and Al₂O₃.

24. An article according to claim 1, wherein the first substrate and/or the second substrate comprises a catalyst.

25. An article according to claim 1, wherein the catalyst comprises Fe, Co, Ni, Mo, or combinations thereof.

26. An article according to claim 1, wherein the thickness of the first substrate is between about 1 Angstrom and about 1 micron.

27. An article according to claim 1, wherein the thickness of the second substrate is between about 1 Angstrom and about 1 micron.

28. An article according to claim 1, wherein the microstructures have an average diameter of 100 nm or less, 50 nm or less, 25 nm or less, or about 10 nm or less.

29. An article according to claim 1, wherein the microstructures have a curvature of greater than about 1 nm, greater than about 5 nm, greater than about 10 nm, greater than about 50 nm, greater than about 100 nm, greater than about 500 nm, greater than about 1 micron, greater than about 5 microns, greater than about 10 microns, greater than about 50 microns, or greater than about 100 microns.

30. A method for growing structures, comprising:
providing a first substrate portion including a first reaction site;
providing a second substrate portion adjacent the first substrate portion including a second reaction site;
introducing a reaction species to the first reaction site and the second reaction site;
growing a first microstructure and/or population of nanostructures on the first reaction site at a first average growth rate;
growing a second microstructure and/or population of nanostructures on the second reaction site at a second average growth rate, wherein the second average growth rate is less than the first average growth rate.

31. A method according to claim 30, wherein the first microstructure and/or second microstructure comprises at least one material selected from the group consisting of nanotubes, nanowires, nanofibers, polymers, metals, ceramic, and biomolecules.

32. A method according to claim 30, wherein the nanotubes are carbon nanotubes.

33. A method according to claim 30, wherein the carbon nanotubes are single-walled carbon nanotubes.

34. A method according to claim 30, wherein the carbon nanotubes are multi-walled carbon nanotubes.

35. A method according to claim 30, wherein the carbon nanotubes have a diameter of less than 100 nm.

36. A method according to claim 30, wherein the first microstructure is in contact with the second microstructure.

37. A method according to claim 30, wherein the first microstructure and the second microstructure are mechanically coupled.

38. A method according to claim 30, wherein a curvature of the first microstructure and/or the second microstructure can be controlled by changing the first average growth rate and/or the second average growth rate.

39. A method according to claim 30, wherein the average growth rate of the first microstructure is at least about 1% greater than the average growth rate of the second microstructure.

40. A method according to claim 30, wherein the average growth rate of the first microstructure is at least about 10% greater than the average growth rate of the second microstructure.

41. A method according to claim 30, wherein the average growth rate of the first microstructure is at least about 100% greater than the average growth rate of the second microstructure.

42. A method according to claim 30, wherein the average growth rate of the first microstructure is at least about 1000% greater than the average growth rate of the second microstructure.

43. A method according to claim 30, wherein the first substrate portion comprises at least one of the group consisting of TiN, SiO₂, and Al₂O₃.

44. A method according to claim 30, wherein the second substrate portion comprises at least one of the group consisting of TiN, SiO₂, and Al₂O₃.

45. A method according to claim 30, wherein the first substrate portion and/or the second substrate portion comprises a catalyst.

46. A method according to claim 30, wherein the first reaction site and/or the second reaction site comprises a catalyst.

47. A method according to claim 30, wherein the catalyst comprises Fe, Co, Ni, Mo, or combinations thereof.

48. A method according to claim 30, wherein the thickness of the first substrate portion is between about 1 Angstrom and about 1 micron.

49. A method according to claim 30, wherein the thickness of the second substrate portion is between about 1 Angstrom and about 1 micron.

50. A method according to claim 30, wherein introducing the reaction species comprises chemical vapor deposition of the reaction species.

51. A method according to claim 30, wherein the method further comprises introducing a coating to the first microstructure and/or the second microstructure.

52. A method according to claim 30, wherein the coating comprises Al₂O₃, metals, metal oxides, or polymers.

53. An method according to claim 30, wherein the microstructures have an average diameter of 100 nm or less, 50 nm or less, 25 nm or less, or about 10 nm or less.

54. A method for growing structures, comprising:
growing at least two microstructures and/or populations of nanostructures, the at least two structures and/or populations have lateral cross-sectional dimensions of at least about 50 nm, simultaneously on a substrate at different growth rates, via exposure to growth conditions applied uniformly to portions of the substrate at which the at least two structures are grown.
